(19) United States
(12) Patent Application Publication
(10) Pub. No.: US 2025/0126810 A1
(43) Pub. Date: Apr. 17, 2025

(54) MEMORY DEVICE

(71) Applicant: SAMSUNG ELECTRONICS CO., LTD., Suwon-si (KR)

(72) Inventors: Changyoung LEE, Suwon-si (KR); Sanghoon Jung, Suwon-si (KR); Youngseok Park, Suwon-si (KR); Changsik Yoo, Suwon-si (KR)

(73) Assignee: SAMSUNG ELECTRONICS CO., LTD., Suwon-si (KR)

(21) Appl. No.: 18/734,650

(22) Filed: Jun. 5, 2024

(30) Foreign Application Priority Data
Oct. 13, 2023 (KR) 10-2023-0137041

(51) Int. Cl. H10B 80/00; H01L 23/00; H01L 25/065; H01L 25/18; H10B 12/00

(52) U.S. Cl. CPC H10B 80/00; H01L 24/08; H01L 25/0657; H01L 25/18; H10B 12/315; H10B 12/50; H01L 2224/08145; H01L 2924/1431; H01L 2924/1436

(57) ABSTRACT

A memory device is provided. The memory device includes: a plurality of sub-array regions arranged spaced apart in a first and second horizontal directions, and each sub-array region including a plurality of memory cells, the first horizontal direction crossing the second horizontal direction; a dummy region disposed between the plurality of sub-array regions, the dummy region including a first metal pattern extending in the first horizontal direction at a first layer, a first lower contact extending in a vertical direction on a first portion of the first metal pattern, and a second lower contact extending in the vertical direction on a second portion of the first metal pattern; and a peripheral circuit region including a first upper contact connected to the first lower contact, a first circuit connected to the first upper contact, a second upper contact connected to the second lower contact, and a second circuit connected to the second upper contact.

### CROSS-REFERENCE TO RELATED APPLICATION

This application claims priority to Korean Patent Application No. 10-2023-0137041, filed on Oct. 13, 2023, in the Korean Intellectual Property Office, the disclosure of which is incorporated by reference herein in its entirety.

### BACKGROUND

The present disclosure relates to electronic devices, and more particularly, to a memory device for arranging at least some wiring of a peripheral circuit in a dummy region.

Semiconductor memory is widely used to store data in various electronic devices such as a computer and a wireless communication device. Dynamic random access memory (DRAM), which is one type of semiconductor memory, operates by writing and reading data due to charges stored in a cell capacitor of a memory cell. In DRAM, a memory cell array is connected to bit lines and word lines. The bit lines are connected to a sense amplifier and the word lines are connected to a word line driving circuit.

### SUMMARY

One or more example embodiments provide a memory device in which at least some wiring of a peripheral circuit is arranged in a dummy region, which may allow for increased memory integration.

According to an aspect of an example embodiment, a memory device includes: a sub-array region extending in a first horizontal direction and a second horizontal direction, and including a plurality of memory cells, the first horizontal direction crossing the second horizontal direction; a dummy region adjacent the sub-array region in the second horizontal direction, the dummy region including a first metal pattern extending in the second horizontal direction through a first layer, a first lower contact extending in a vertical direction on a first portion of the first metal pattern, and a second lower contact extending in the vertical direction on a second portion of the first metal pattern; and a peripheral circuit region including a first upper contact connected to the first lower contact, a first circuit connected to the first upper contact, a second upper contact connected to the second lower contact, and a second circuit connected to the second upper contact.

According to another aspect of an example embodiment, a memory device including: a sub-array region including a plurality of memory cells; a dummy region adjacent the sub-array region, the dummy region including a first power metal pattern extending in a first horizontal direction through a first layer, a first lower contact extending in a vertical direction on the first power metal pattern, a second power metal pattern extending in a second horizontal direction through a second layer, and a second lower contact extending in the vertical direction on the second power metal pattern; and a peripheral circuit region including a first upper contact connected to the first lower contact, a first power circuit connected to the first upper contact, a second upper contact connected to the second lower contact, and a second power circuit connected to the second upper contact.

According to another aspect of an example embodiment, a memory device includes: a sub-array region including a plurality of memory cells; a dummy region adjacent the sub-array region, the dummy region including a first metal pattern extending in a first horizontal direction through a first layer, a first via contact extending in a vertical direction on the first metal pattern, a second metal pattern in contact with the first via contact at a second layer and extending in a second horizontal direction, a first lower contact extending in the vertical direction on the first metal pattern, and a second lower contact extending in the vertical direction on the second metal pattern; and a peripheral circuit region including a first upper contact connected to the first lower contact, a first test circuit connected to the first upper contact, a second upper contact connected to the second lower contact, and a second test circuit connected to the second upper contact.

### BRIEF DESCRIPTION OF DRAWINGS

The above and other aspects will be more apparent from the following description of example embodiments, taken in conjunction with the accompanying drawings, in which:

FIG. 1 is a schematic diagram of a structure of a memory device according to example embodiments;

FIG. 2 is a cross-sectional view of the memory device taken along line A1-A2 of FIG. 1;

FIG. 3 is a view for explaining signal movement within a peripheral circuit according to some example embodiments;

FIG. 4 is a cross-sectional view of the memory device taken along line B1-B2 of FIG. 3;

FIG. 5 is a view for explaining signal movement within a peripheral circuit according to other example embodiments;

FIG. 6 is a cross-sectional view of a memory device taken along line C1-C2 of FIG. 5;

FIG. 7 is a cross-sectional view of the memory device taken along line D1-D2 of FIG. 5;

FIG. 8 is a view for explaining a power network according to example embodiments;

FIG. 9 is a cross-sectional view of a memory device taken along line E1-E2 of FIG. 8;

FIG. 10 is a cross-sectional view of the memory device taken along line F1-F2 of FIG. 8;

FIGS. 11 and 12 are cross-sectional views of semiconductor devices according to some example embodiments;

FIGS. 13 and 14 are cross-sectional views of other semiconductor devices according to other example embodiments;

FIGS. 15 and 16 are cross-sectional views of semiconductor devices according to other example embodiments; and

FIGS. 17 and 18 are cross-sectional views of semiconductor devices according to other example embodiments.

### DETAILED DESCRIPTION

Hereinafter, example embodiments of the present disclosure will be described more fully with reference to the accompanying drawings, in which example embodiments of the present disclosure are shown. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element or layer is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

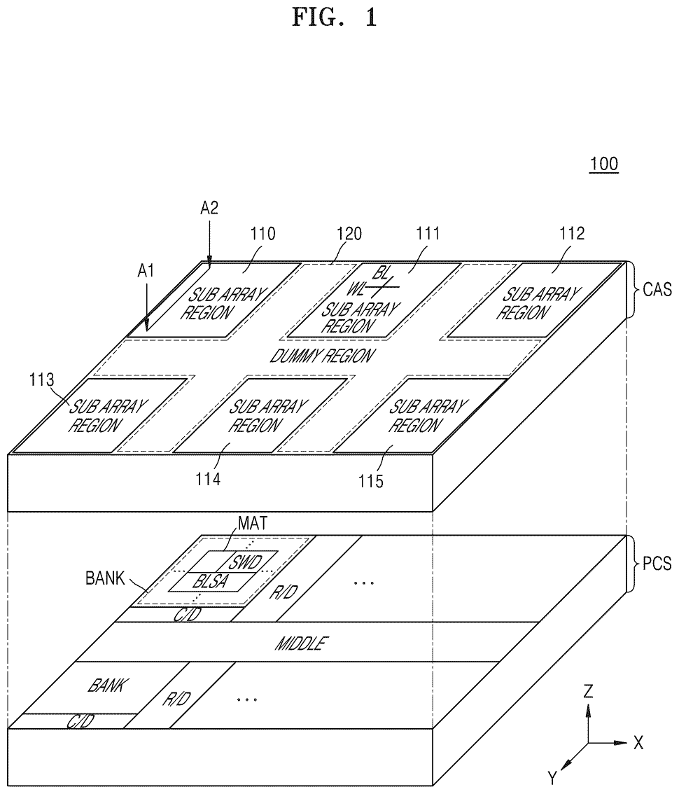

FIG. 1 is a schematic diagram of a structure of a memory device 100 according to example embodiments.

Referring to FIG. 1, the memory device 100 correspond to double data rate synchronous dynamic random access memory (DDR SDRAM), low power double data rate (LPDDR) SDRAM, graphics double data rate (GDDR) SDRAM, or Rambus DRAM (RDRAM).

The memory device 100 may include a cell array structure CAS and a peripheral circuit structure PCS. The cell array structure CAS may be disposed over the peripheral circuit structure PCS in a vertical direction (e.g., a Z direction) with respect to the peripheral circuit structure PCS. In this regard, the peripheral circuit structure PCS may be buried and disposed below the cell array structure CAS in a direction perpendicular to the cell array structure CAS. According to an example embodiment, the cell array structure CAS and the peripheral circuit structure PCS may be attached to each other through pads in the vertical direction (e.g., a Z direction). The attachment may be achieved by, for example, bonding between copper (Cu) pads, but example embodiments are not limited thereto.

The cell array structure CAS may include a plurality of sub-array regions 110, 111, 112, 113, 114, and 115 and a dummy region 120.

Each of the plurality of sub-array regions 110, 111, 112, 113, 114, and 115 may include a plurality of word lines, a plurality of bit lines, and a plurality of memory cells. A bit line BL included in each sub-array region may each extend in a first horizontal direction (e.g., a Y direction) and may be arranged side by side in a second horizontal direction (e.g., an X direction). A word line WL included in each sub-array region may each extend in the second horizontal direction (e.g., the X direction) and may be arranged side by side in the first horizontal direction (e.g., the Y direction). Each of the plurality of memory cells may be connected to a bit line BL and a word line WL. Each of the plurality of memory cells may include a cell transistor and a cell capacitor. Each of the plurality of memory cells formed in the plurality of sub-array regions 110, 111, 112, 113, 114, and 115 may include a cell transistor and a cell capacitor connected to the bit line BL and the word line WL. Each of the plurality of sub-array regions 110, 111, 112, 113, 114, and 115 may include a plurality of memory blocks. Memory cells connected to a plurality of word lines WL may constitute one memory block. Each of the plurality of sub-array regions 110, 111, 112, 113, 114, and 115 may be arranged such that at least one side of each of the plurality of sub-array regions 110, 111, 112, 113, 114, and 115 may be spaced apart from another sub-array region. Each of the plurality of sub-array regions 110, 111, 112, 113, 114, and 115 may include a plurality of pads formed such that the peripheral circuit structure PCS is connected to each of the bit lines and the word lines. For example, each sub-array region may include first pads and second pads. The first pads may connect a bit line sense amplifier BLSA of the peripheral circuit structure PCS to the bit line BL. The second pads may connect a sub word line driver SWD of the peripheral circuit structure PCS to the word line WL.

The dummy region 120 may be disposed between the plurality of sub-array regions 110, 111, 112, 113, 114, and 115. For example, the dummy region 120 may be disposed between two different sub-array regions. The dummy region 120 may be disposed side by side with corresponding sub-array regions in the first and second horizontal directions. The dummy region 120 may include a plurality of pads connected to the peripheral circuit structure PCS. According to an example embodiment, the dummy region 120 may not include a plurality of bit lines, a plurality of word lines, and a plurality of memory cells.

The peripheral circuit structure PCS may include a peripheral circuit region where a peripheral circuit is formed. Some peripheral circuits may be formed in a portion of the peripheral circuit region. Some other peripheral circuits may be formed in another portion of the peripheral circuit region. The peripheral circuit may be configured to apply a word line driving voltage to a word line (e.g., WL) selected from the plurality of word lines. The peripheral circuit may be configured to sense data through at least one bit line selected from the plurality of bit lines. The peripheral circuit may include a row decoder R/D (e.g., a row decoder circuit) and a column decoder C/D (e.g., a column decoder circuit), for example.

For example, in a middle region MIDDLE of the peripheral circuit structure PCS, although not specifically shown in FIG. 1, a command decoder (e.g., a command decoder circuit), a mode register set/extended mode register set (MRS/EMRS) circuit, an address buffer, a data input/output circuit, a voltage generation circuit, a text circuit, etc., may be included. The command decoder may receive command signals applied by an external source, and decode these signals to internally generate commands according to the decoded command signals. The MRS/EMRS circuit may set an internal mode resistor in response to an MRS/EMRS command and an address signal both for designating an operation mode of the memory device 100. Data input through the data input/output circuit may be written to each sub-array, or data read from each sub-array may be output to the outside through the data input/output circuit. The address buffer may temporarily store an address signal input from an external source. The voltage generation circuit may generate various internal voltages that drive circuits of the memory device 100. The voltage generation circuit may generate a high voltage (e.g., VPP), a negative voltage (e.g., VBB), a bit line precharge voltage (e.g., VEQ), an internal power supply voltage (e.g. VINTA), etc., by using a power supply voltage (e.g., VDD) applied from the outside of the memory device 100. The high voltage (e.g., VPP) may be provided to the row decoder R/D, may have a voltage level higher than the power supply voltage (e.g., VDD), and may be used in word line driving circuits for turning on an N-type metal oxide semiconductor (NMOS) cell transistor connected to the word lines WL. The negative voltage (e.g., VBB) may have a negative (−) voltage level lower than the power supply voltage (e.g., VDD), and may be used to increase a data retention time by increasing the threshold voltage (e.g., Vth) of an NMOS transistor. The negative voltage (e.g., VBB) may be applied to a well region where the NMOS transistor is formed, and may be commonly referred to as a bulk bias voltage or back bias voltage. The bit line precharge voltage (e.g., VEQ) may be used to equalize a voltage of the bit line BL and a voltage of a complementary bit line (e.g., BIT LINE BAR), before the bit line sense amplifier BLSA senses a voltage difference between the bit line BL and the complementary bit line. The internal power supply voltage (e.g., VINTA) may be provided to first and second sensing driving voltage lines (e.g., LA and LAB) of the bit line sense amplifier BLSA. The bit line sense amplifier BLSA may sense and amplify the voltage difference between the bit line BL and the complementary bit line according to the first and second sensing driving voltage lines (e.g., LA and LAB). The test circuit may perform a test operation within the memory device 100. For example, the test circuit may be a tester that outputs a test mode signal. As another example, the test circuit may include a test MRS (TMRS) fuse box that outputs a TMRS signal for a TMRS.

For example, each of the regions other than the middle region MIDDLE of the peripheral circuit structure PCS may include a row decoder R/D, a column decoder C/D, and a bank BANK. The bank BANK may include one or more mat regions MAT. The mat region may be referred to as a mat. One mat region MAT may include a bit line sense amplifier BLSA and a sub word line driver SWD. One mat region MAT may further include a conjunction corresponding to the intersection of the bit line sense amplifier BLSA and the sub word line driver SWD. The conjunction may include switches for driving the bit line sense amplifier BLSA and the sub word line driver SWD. The row decoder R/D may decode a row address among address signals output by the address buffer, in order to designate a word line connected to the memory cell to or from which data is to be input or output, and may select the word line. The row decoder R/D may generate a word line driving voltage to be applied to the word line corresponding to the row address. The row decoder R/D may be connected to the sub word line driver SWD. The sub word line driver SWD may be connected to a plurality of word lines formed in each sub-array region. The sub word line driver SWD may drive at least part of the plurality of word lines by transmitting the word line driving voltage to the word lines. The column decoder C/D may select at least one bit line corresponding to a column address. The column decoder C/D may decode a column address among the address signals output by the address buffer, in order to designate a bit line connected to the memory cell to or from which data is to be input or output. The column decoder C/D may be connected to the bit line sense amplifier BLSA. The bit line sense amplifier BLSA may be connected to a plurality of bit lines formed in each sub-array region, and may read data from or write data to memory cells formed in each sub-array area.

Because the memory device 100 includes the cell array structure CAS and the peripheral circuit structure PCS of a stack structure, word lines may extend without interruption by circuit configurations other than memory cells in the cell array structure CAS. In other words, the memory device 100 may include the cell array structure CAS and the peripheral circuit structure PCS of a stack structure, and word lines may extend without interruption by circuit configurations other than memory cells in the cell array structure CAS.

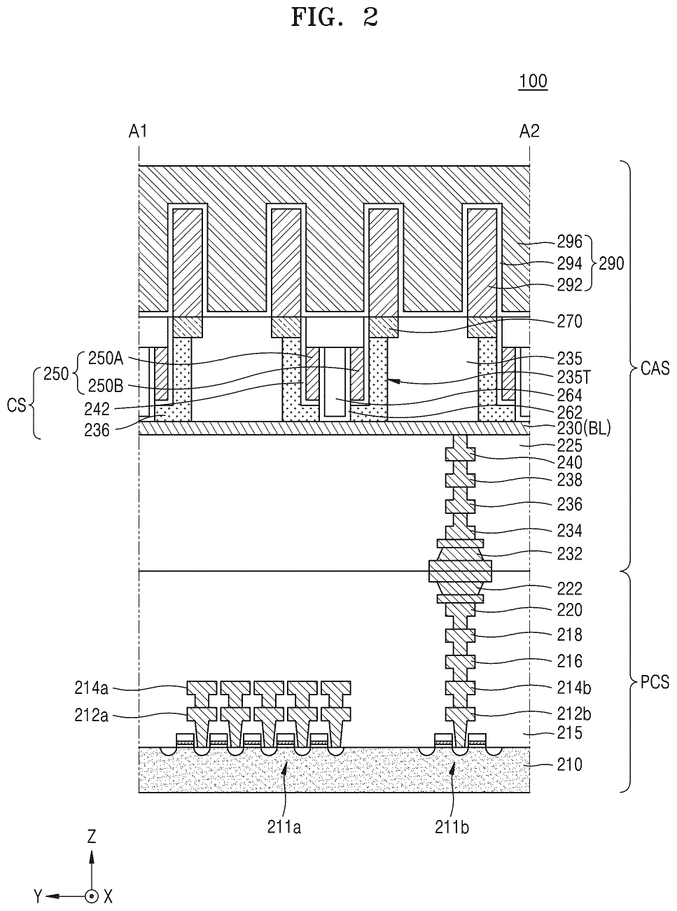

FIG. 2 is a cross-sectional view of the memory device 100 taken along line A1-A2 of FIG. 1.

Referring to FIG. 2, the memory device 100 may include the cell array structure CAS and the peripheral circuit structure PCS bonded to each other in the vertical direction (e.g., the Z direction). Because the cell array structure CAS may include the plurality of sub-array regions 110, 111, 112, 113, 114, and 115 and the peripheral circuit structure PCS may include the peripheral circuit, the memory device 100 may have a structure in which a sub-array is disposed over the peripheral circuit, that is, a Cell over Periphery (CoP) structure.

According to an example embodiment, the cell array structure CAS may include a memory cell including a vertical channel transistor. However, an example embodiment is not limited thereto, and the cell array structure CAS may include a memory cell including a different type of transistor from the vertical channel transistor. The bit line BL may extend in the first horizontal direction (e.g., the Y direction), and the word line WL may extend in the second horizontal direction (e.g., the X direction). Each of the number of memory cells, the number of bit lines, and the number of word lines may be plural.

The peripheral circuit structure PCS may include a semiconductor substrate. The peripheral circuit may be formed by forming, on the semiconductor substrate, semiconductor devices, such as transistors, and a pattern for wiring the semiconductor devices. After the peripheral circuit is formed in the peripheral circuit structure PCS, the cell array structure CAS including the plurality of sub-array regions 110, 111, 112, 113, 114, 115 and the dummy region 120 may be formed, and patterns may be formed to electrically connect the word line WL and the bit line BL of each sub-array region to the peripheral circuit formed in the peripheral circuit structure PCS.

The peripheral circuit structure PCS may include a substrate 210, a first interlayer insulating layer 215, a plurality of circuit devices 211a and 211b formed on the substrate 210, first metal patterns 212a and 212b connected to the plurality of circuit devices 211a and 211b, respectively, second metal patterns 214a and 214b formed on the first metal patterns 212a and 212b, a third metal pattern 216 formed on the second metal pattern 214b, a fourth metal pattern 218 formed on the third metal pattern 216, a fifth metal pattern 220 formed on the fourth metal pattern 218, and a first contact pad 222 formed on the fifth metal pattern 220.

Although only the first metal pattern 212a and the second metal pattern 214a are shown in FIG. 2, example embodiments are not limited thereto, and at least one metal pattern may be further formed on the second metal pattern 214a. The metal pattern may also be referred to as a metal layer. According to an example embodiment, the metal pattern may include one or more metal lines each extending in one horizontal direction and arranged side by side in another horizontal direction. Only the first metal pattern 212b, the second metal pattern 214b, the third metal pattern 216, the fourth metal pattern 218, and the fifth metal pattern 220 are shown in FIG. 2, but example embodiments are not limited thereto. Fewer than five metal patterns may be stacked, or at least one metal pattern may be further formed on the fifth metal pattern 220. According to an example embodiment, the first metal patterns 212a and 212b may be formed of tungsten with a relatively high resistance, and the second metal patterns 214a and 214b may be formed of copper with a relatively low resistance. At least part of the one or more metal patterns formed above the second metal patterns 214a and 214b may be formed of metal having a lower resistance than that of copper used to form the second metal patterns 214a and 214b.

The first interlayer insulating layer 215 may be disposed on the substrate 210. The first interlayer insulating layer 215 may cover the plurality of circuit devices 211a and 211b, the first metal patterns 212a and 212b, the second metal patterns 214a and 214b, the third metal pattern 216, the fourth metal pattern 218, the fifth metal pattern 220, and the first contact pad 222. The first interlayer insulating layer 215 may be formed of an insulating material, such as silicon oxide or silicon nitride.

The plurality of circuit devices 211a and 211b may be connected to at least one of the circuit devices constituting the peripheral circuit. For example, the first circuit device 211a may be one of the transistors included in the sub word line driver SWD. The second circuit device 211b may be any one of the transistors included in the bit line sense amplifier BLSA. However, example embodiments are not limited thereto.

The first contact pad 222 may be disposed on a metal pattern disposed at an uppermost (or topmost, highest) layer of the peripheral circuit structure PCS, and may be bonded to a second contact pad 232. The second contact pad 232 may be formed of copper, but example embodiments are not limited thereto. The first and second contact pads 222 and 232 may each include a plurality of layers having different widths. A middle layer of the contact pads 222 and 232 may have a width that varies.

The cell array structure CAS may include the second contact pad 232, a plurality of metal patterns 234, 236, 238, and 240 stacked on the second contact pad 232, a second interlayer insulating layer 225, a conductive line 230 disposed on the second interlayer insulating layer 225, a cell structure CS disposed on the conductive line 230, and a capacitor structure 290 disposed on the cell structure CS.

The second contact pad 232 may be disposed below a metal pattern disposed at a lowest (or, downmost, bottom) layer of the cell array structure CAS, and may be bonded to the first contact pad 222. The second contact pad 232 may be formed of copper, but example embodiments are not limited thereto.

In FIG. 2, the cell array structure CAS includes four metal patterns 234, 236, 238 and 240. However, example embodiments are not limited thereto, and fewer than the four metal patterns may be stacked, or at least one metal pattern may be further formed on the second contact pad 232 and below the conductive line 230. According to example embodiments, the plurality of metal patterns 234, 236, 238, and 240 may be formed of a material with a specific resistance (e.g., copper, tungsten, or aluminum).

The second interlayer insulating layer 225 may be formed to cover a lateral surface of the second contact pad 232, respective lateral surfaces of the plurality of metal patterns 234, 236, 238, and 240, and lower and lateral surfaces of the conductive line 230. The second interlayer insulating layer 225 may be formed to fill a space between the second contact pad 232, the plurality of metal patterns 234, 236, 238, and 240, and the conductive line 230.

The conductive line 230 may extend in the first horizontal direction (e.g., the Y direction). A plurality of conductive lines including the conductive line 230 may be spaced apart from each other in the second horizontal direction (e.g., the X direction) intersecting the first horizontal direction (e.g., the Y direction). The conductive line 230 may function as the bit line BL of the memory device 100.

An isolation insulating layer 235 may be formed on the conductive line 230. The isolation insulating layer 235 may include channel trenches 235T, and may include a plurality of insulating patterns spaced apart from each other by the channel trenches 235T. A channel layer 246 may be formed within each of the channel trenches 235T. The channel layer 246 may extend along lateral and lower surfaces of the channel trench 235T and may be electrically connected to the conductive line 230. A gate dielectric layer 242 may be formed on the channel layer 246 within the channel trench 235T. The gate dielectric layer 242 may be interposed between the channel layer 246 and a gate electrode 250. The gate electrode 250 may be formed on the gate dielectric layer 242 within the channel trench 235T. According to an example embodiment, the gate electrode 250 may include a first gate electrode 250A and a second gate electrode 250B facing each other within one channel trench 235T. In this case, two transistor structures may be implemented per one channel layer 246. The first gate electrode 250A may function as a first word line of a sub-array, and the second gate electrode 250B may function as a second word line of the sub-array. According to an example embodiment, the first gate electrode 250A may function as a forward gate electrode of a cell transistor connected to a word line, and the second gate electrode 250B may function as a back gate electrode of the cell transistor.

According to an example embodiment, a barrier insulating layer 262 and a gap fill insulating layer 264 may be formed between the first gate electrode 250A and the second gate electrode 250B. The first gate electrode 250A and the second gate electrode 250B may be separated from each other by the barrier insulating layer 262 and the gap fill insulating layer 264. The gap fill insulating layer 264 may be formed on the barrier insulating layer 262 to fill an area between the first gate electrode 250A and the second gate electrode 250B.

According to an example embodiment, a cell structure CS may include a structure of a vertical channel transistor. However, example embodiments are not limited thereto. In some cases, the cell structure CS may include a structure of a different transistor from the vertical channel transistor. A vertical channel transistor according to an example embodiment may refer to a structure in which a channel length of the channel layer 246 extends in a vertical direction (e.g., the Z direction) perpendicular to an upper surface of the substrate 210. The vertical channel transistor may include the channel layer 246, the gate electrode 250, and the gate dielectric layer 242 interposed between the channel layer 246 and the gate electrode 250. The channel layer 246 of the vertical channel transistor may include a first source/drain region and a second source/drain region arranged in the vertical direction (e.g., the Z direction). For example, a lower portion of the channel layer 246 may function as the first source/drain region, and an upper portion of the channel layer 246 may function as the second source/drain region. A portion of the channel layer 246 between the first source/drain region and the second source/drain region may function as a channel region.

Contact layers 270 connected to the upper surface of the channel layer 246 may be formed on the channel layer 246. The contact layers 270 may connect the channel layer 246 to a capacitor structure 290. An upper surface of the channel layer 246 adjacent to the first gate electrode 250A may be connected to one contact layer 270, and an upper surface of the channel layer 246 adjacent to the second gate electrode 250B may be connected to another contact layer 270.

The capacitor structure 290 may be formed on the isolation insulating layer 235 and the contact layers 270. The capacitor structure 290 may be connected to respective upper surfaces of the contact layers 270. The capacitor structure 290 may be controlled by signals conducted by the conductive line 230 and the gate electrode 250 to store data. The capacitor structure 290 may include a lower electrode 292, a capacitor dielectric layer 294, and an upper electrode 296. The capacitor structure 290 may store charges in the capacitor dielectric layer 294 by using a potential difference generated between the lower electrode 292 and the upper electrode 296.

Because one of a plurality of vertical channel transistor structures and one of capacitor structures 290 may constitute a memory cell, the cell array structure CAS may include a plurality of memory cells constituted by a plurality of cell structures CS and a plurality of capacitor structures 290.

As high-performance and high-integration memory devices are required, the integration and complexity of the peripheral circuit within the peripheral circuit structure PCS may increase, and the complexity of wiring for signal communication between circuits (e.g., the row decoder R/D and the column decoder C/D) may also increase. In order to increase a signal speed between circuits of a high-performance peripheral circuit, wiring for signal communication needs to be disposed relatively simply. However, due to limitations in the physical size of the peripheral circuit structure PCS, a location (or space) where to arrange wiring for connecting circuits to each other within the peripheral circuit structure PCS may be insufficient. To address this situation, it is necessary to place the wiring for connecting the circuits of the peripheral circuit structure PCS in the dummy region 120 of the cell array structure CAS.

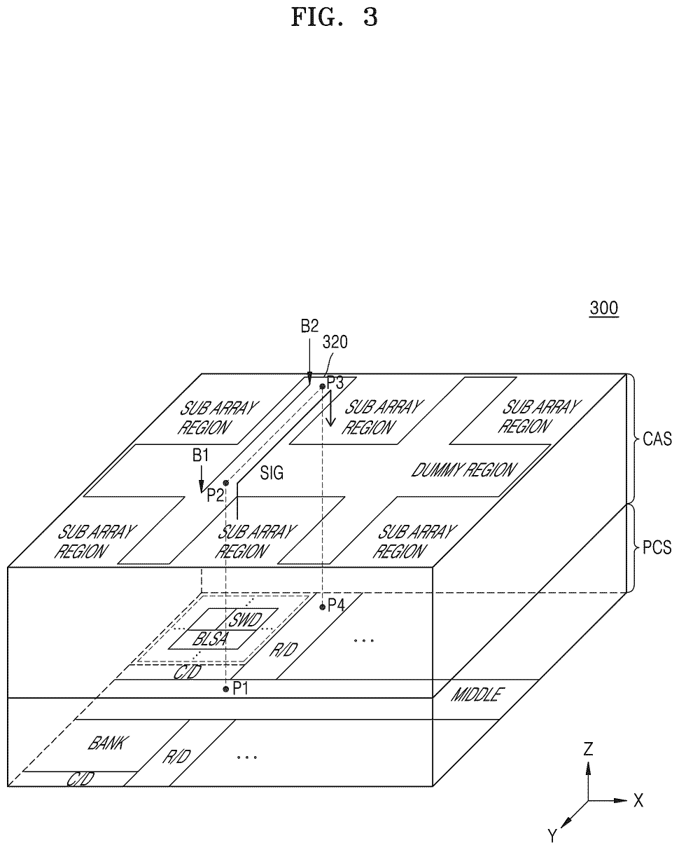

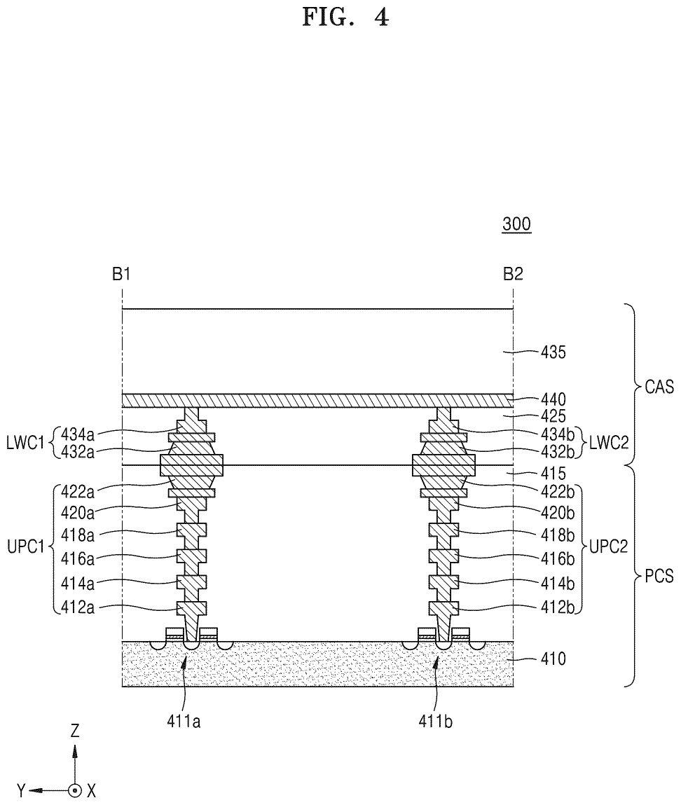

FIG. 3 is a view for explaining signal movement within a peripheral circuit according to an example embodiment. FIG. 4 is a cross-sectional view of the memory device taken along line B1-B2 of FIG. 3.

Referring to FIG. 3, wirings for signal transmission between the circuits of a peripheral circuit structure PCS may be arranged in a dummy region 320 of a cell array structure CAS. For example, a wiring for conducting a signal indicating an address from an address buffer included in a middle region MIDDLE to a row decoder R/D may be disposed in the dummy region 320. However, example embodiments are not limited thereto. A signal SIG output by a first circuit located at a first point P1 may be transmitted to a second circuit through wiring. A path of the signal SIG transmitted through the wiring may be, for example, a path passing through the first point P1, a second point P2, a third point P3, and a fourth point P4. For example, a specific circuit device included in the address buffer of the middle region MIDDLE may transmit the signal SIG corresponding to an address from the first point P1 to the second point P2, and the signal SIG may move from the second point P2 to the fourth point P4 via the third point P3. The specific circuit device of the row decoder R/D located at the fourth point P4 may receive the signal SIG.

Referring to FIGS. 3 and 4, a peripheral circuit region of the peripheral circuit structure PCS may include a substrate 410, a first circuit device 411a, a second circuit device 411b, a first interlayer insulating layer 415, a first upper contact UPC1, and a second upper contact UPC2.

The substrate 410 and the first interlayer insulating layer 415 may be the same as the substrate 210 and the first interlayer insulating layer 215 of FIG. 2.

The first circuit device 411a may be a device included in a first circuit. The second circuit device 411b may be a device included in a second circuit. For example, the first circuit device 411a may be a transistor included in the address buffer, and the second circuit device 411b may be a transistor included in the row decoder R/D. However, example embodiments are not limited thereto.

The first upper contact UPC1 may be disposed on the first circuit device 411a. The first upper contact UPC1 may be attached to a first lower contact LWC1. According to an example embodiment, the first upper contact UPC1 may include at least one contact metal pattern that is in contact with the first circuit device 411a and stacked in a direction toward the dummy region 320, and a contact pad 422a. For example, the first upper contact UPC1 may include first, second, third, fourth, and fifth contact metal patterns 412a, 414a, 416a, 418a, and 420a and the contact pad 422a. The first contact metal pattern 412a may be disposed on the first circuit device 411a. For example, one surface of the first contact metal pattern 412a may be in contact with the first circuit device 411a. Another surface of the first contact metal pattern 412a may be in contact with the second contact metal pattern 414a. The second, third, fourth, and fifth contact metal patterns 414a, 416a, 418a, and 420a may be stacked in the vertical direction (e.g., the Z direction). The contact pad 422a may be disposed on the fifth contact metal pattern 420a. For example, one surface of the contact pad 422a may be in contact with the fifth contact metal pattern 420a, and another surface of the contact pad 422a may be in contact with a contact pad 432a of the first lower contact LWC1. The contact pad 422a may be formed of copper, but example embodiments are not limited thereto. The contact pad 422a may include a plurality of layers having different widths. A middle layer of the contact pad 422a may have a width that varies.

The second upper contact UPC2 may be disposed on the second circuit device 411b. The second upper contact UPC2 may be attached to a second lower contact LWC2. According to an example embodiment, the second upper contact UPC2 may include at least one contact metal pattern that is in contact with the second circuit device 411b and stacked in a direction toward the dummy region 320, and a contact pad 422b. For example, the second upper contact UPC2 may include first, second, third, fourth, and fifth contact metal patterns 412b, 414b, 416b, 418b, and 420b and the contact pad 422b. The first contact metal pattern 412b may be disposed on the second circuit device 411b. For example, one surface of the first contact metal pattern 412b may be in contact with the second circuit device 411b. Another surface of the first contact metal pattern 412b may be in contact with the second contact metal pattern 414b. The second, third, fourth, and fifth contact metal patterns 414b, 416b, 418b, and 420b may be stacked in the vertical direction (e.g., the Z direction). The contact pad 422b may be disposed on the fifth contact metal pattern 420b. For example, one surface of the contact pad 422b may be in contact with the fifth contact metal pattern 420b, and another surface of the contact pad 422b may be in contact with a contact pad 432b of the second lower contact LWC2. The contact pad 422b may be formed of copper, but example embodiments are not limited thereto. The contact pad 422b may include a plurality of layers having different widths. A middle layer of the contact pad 422b may have a width that varies.

The dummy region 320 may include a second interlayer insulating layer 425, the first lower contact LWC1, the second lower contact LWC2, a first metal pattern 440, and a third interlayer insulating layer 435.

The second interlayer insulating layer 425 may be formed to cover a lateral surface of the first lower contact LWC1, a lateral surface of the second lower contact LWC2, and lower and lateral surfaces of the first metal pattern 440. The second interlayer insulating layer 425 may be formed to fill a space between the first lower contact LWC1, the second lower contact LWC2, and the first metal pattern 440.

The first lower contact LWC1 may be disposed on the first upper contact UPC1 and may be attached to the first upper contact UPC1. According to an example embodiment, the first lower contact LWC1 may include a contact pad 432a and a contact metal pattern 434a. The contact pad 432a may be disposed on the contact pad 422a of the first upper contact UPC1. For example, one surface of the contact pad 432a may be in contact with the contact pad 422a of the first upper contact UPC1, and another surface of the contact pad 432a may be in contact with the contact metal pattern 434a. The contact pad 432a may be formed of copper, but example embodiments are not limited thereto. The contact pad 432a may include a plurality of layers having different widths. A middle layer of the contact pad 432a may have a width that varies. The contact metal pattern 434a may be disposed on the contact pad 432a. The contact metal pattern 434a may be stacked on a first portion of the first metal pattern 440 in a direction toward the peripheral circuit region of the peripheral circuit structure PCS.

The second lower contact LWC2 may be disposed on the second upper contact UPC2 and may be attached to the second upper contact UPC2. According to an example embodiment, the second lower contact LWC2 may include a contact pad 432b and a contact metal pattern 434b. The contact pad 432b may be disposed on the contact pad 422b of the second upper contact UPC2. For example, one surface of the contact pad 432b may be in contact with the contact pad 422b of the second upper contact UPC2, and another surface of the contact pad 432b may be in contact with the contact metal pattern 434b. The contact pad 432b may be formed of copper, but example embodiments are not limited thereto. The contact pad 432b may include a plurality of layers having different widths. A middle layer of the contact pad 432b may have a width that varies. The contact metal pattern 434b may be disposed on the contact pad 432b. The contact metal pattern 434b may be stacked on a second portion of the first metal pattern 440 in a direction toward the peripheral circuit region of the peripheral circuit structure PCS.

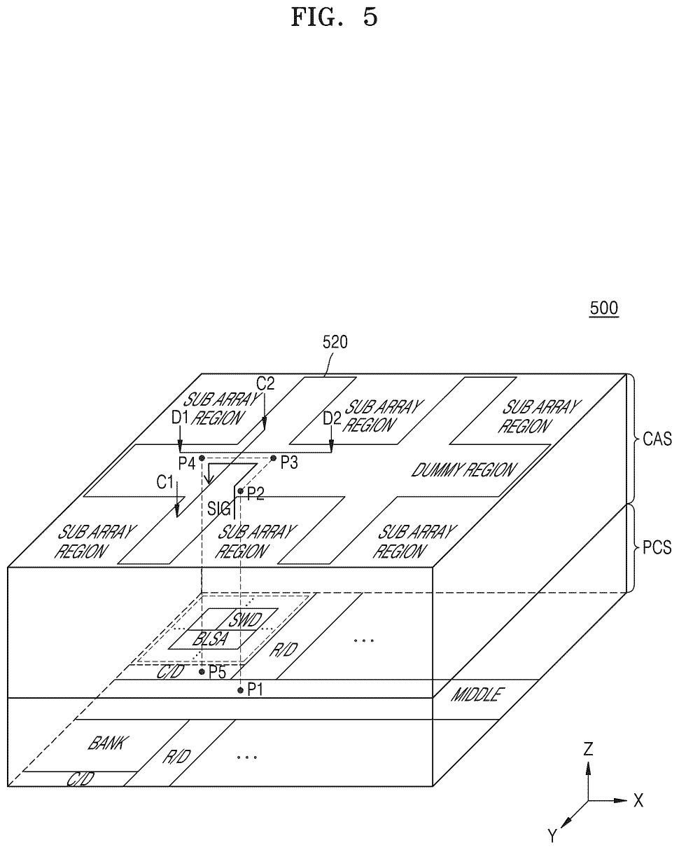

The first metal pattern 440 may extend at a first layer in the horizontal direction. Referring to FIG. 4, for example, the first layer may be located between the second insulating layer 425 and the third insulating layer 435, and the first metal pattern 440 may extend in the first horizontal direction (e.g., the Y direction). However, example embodiments are not limited thereto. In contrast with FIGS. 4 and 5, for example, the first metal pattern 440 may extend in the second horizontal direction (e.g., the X direction). One or more first metal patterns 440 may be provided. Referring to FIG. 4, for example, two or more first metal patterns 440 may be arranged side by side in the second horizontal direction (e.g., the X direction). At least one first metal pattern 440 may be composed of a metal line, but example embodiments are not limited thereto. The first lower contact LWC1 may be in contact with the first portion of the first metal pattern 440. The second lower contact LWC2 may be in contact with the second portion of the first metal pattern 440. The first metal pattern 440 may be formed of a material with a relatively low resistance (e.g., copper or aluminum). A signal SIG between the first circuit device 411a and the second circuit device 411b may be transmitted through the first metal pattern 440.

The third interlayer insulating layer 435 may be formed to cover upper and lateral surfaces of the first metal pattern 440 and fill a space between one first metal pattern 440 and another first metal pattern 440.

As discussed above, by disposing at least part of wirings of the peripheral circuit structure PCS in the dummy region 320 of the cell array structure CAS, the integration degree of the memory device 300 is increased, and the efficiency of the peripheral circuit region is improved.

In addition, by arranging wiring with a relatively low resistance in a simple pattern in the dummy region 320 of the cell array structure CAS, a signal speed of the peripheral circuit is increased, and performance of the memory device 300 is increased.

For efficiency of resources (e.g., a physical size of the peripheral circuit structure PCS), wiring for the peripheral circuit may be arranged in a relatively more complex pattern than the pattern shown in FIG. 4. Alternatively, a test circuit included in the memory device 300 may perform operations through relatively slow signal communication. In this case, even when wiring for the test circuit is arranged in the dummy region 320 in a relatively complex pattern, the test circuit may operate smoothly.

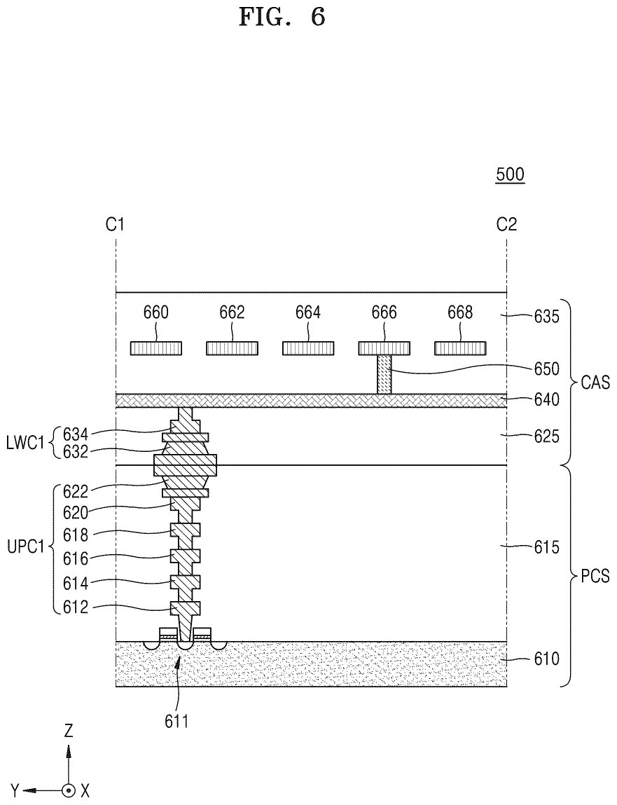

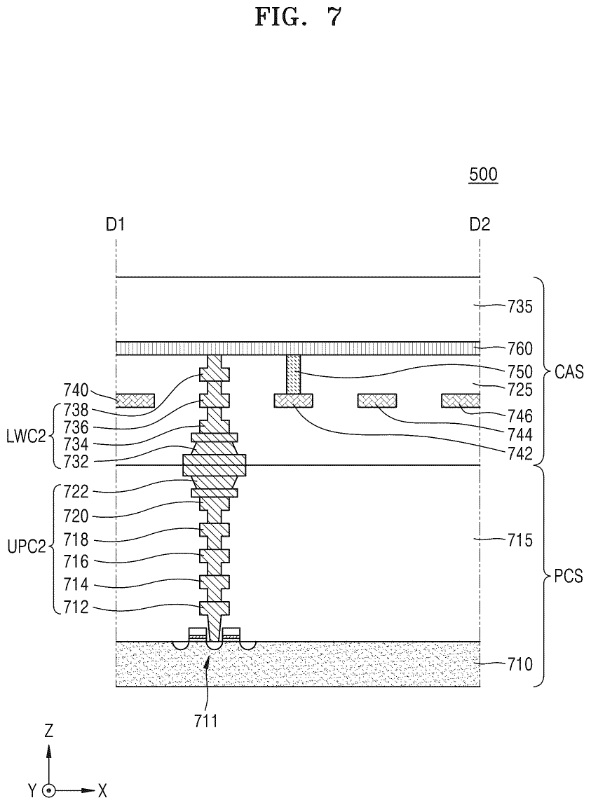

FIG. 5 is a view for explaining signal movement within a peripheral circuit according to other example embodiments. FIG. 6 is a cross-sectional view of a memory device taken along line C1-C2 of FIG. 5. FIG. 7 is a cross-sectional view of the memory device taken along line D1-D2 of FIG. 5.

Referring to FIG. 5, wirings for connecting the circuits of a peripheral circuit structure PCS to each other may be arranged in a dummy region 520 of a cell array structure CAS. For example, wirings for conducting a signal indicating an address from an address buffer included in a middle region MIDDLE to a column decoder C/D may be disposed in the dummy region 520. As another example, wirings used by a TMRS fuse box included in a middle region MIDDLE to transmit a TMRS signal to another circuit may be disposed in the dummy region 520. A signal SIG output by a first circuit located at a first point P1 may be transmitted to a third circuit through wiring. A path of the signal SIG transmitted through the wiring may be, for example, a path passing through the first point P1, a second point P2, a third point P3, a fourth point P4, and a fifth point P5.

Referring to FIGS. 5 and 6, a peripheral circuit region of the peripheral circuit structure PCS may include a substrate 610, a first circuit device 611, a first interlayer insulating layer 615, and a first upper contact UPC1. The substrate 610 and the first interlayer insulating layer 615 may be the same as the substrate and the first interlayer insulating layer described above with reference to FIGS. 2 and 4.

According to an example embodiment, the first circuit device 611 may be included in a first circuit including the first circuit device 411a of FIG. 4. For example, the first circuit device 611 may be a transistor included in the address buffer. However, example embodiments are not limited thereto, and the first circuit device 611 may be included in a different circuit from the first circuit of FIG. 4.

According to other example embodiments, the first circuit device 611 may be included in a test circuit. The test circuit may be, for example, a TMRS fuse box, but example embodiments are not limited thereto. A circuit device included in the test circuit may be referred to as a test circuit device.

The first upper contact UPC1 may be disposed on the first circuit device 611, and may be attached to a first lower contact LWC1. According to an example embodiment, the first upper contact UPC1 may include at least one contact metal pattern that is in contact with the first circuit device 611 and stacked in a direction toward the dummy region 520, and a contact pad 622. For example, the first upper contact UPC1 may include first, second, third, fourth, and fifth contact metal patterns 612, 614, 616, 618, and 620 and the contact pad 622. The first contact metal pattern 612 may be disposed on the first circuit device 611. For example, one surface of the first contact metal pattern 612 may be in contact with the first circuit device 611. Another surface of the first contact metal pattern 612 may be in contact with the second contact metal pattern 614. The second, third, fourth, and fifth contact metal patterns 614, 616, 618, and 620 may be stacked in the vertical direction (e.g., the Z direction). The contact pad 622 may be disposed on the fifth contact metal pattern 620. For example, one surface of the contact pad 622 may be in contact with the fifth contact metal pattern 620, and another surface of the contact pad 622 may be in contact with a contact pad 632 of the first lower contact LWC1. The contact pad 622 may be formed of copper, but example embodiments are not limited thereto. The contact pad 622 may include a plurality of layers having different widths. A middle layer of the contact pad 622 may have a width that varies.

The dummy region 520 may include a second interlayer insulating layer 625, the first lower contact LWC1, at least one first metal pattern 640, a via contact 650, a third interlayer insulating layer 635, and at least one second metal pattern (e.g., 660, 662, 664, 666, and/or 668).

The second interlayer insulating layer 625 may be formed to cover a lateral surface of the first lower contact LWC1 and lower and lateral surfaces of the first metal pattern 640. The second interlayer insulating layer 625 may be formed to fill a space between the first lower contact LWC1 and the first metal pattern 640.

The first lower contact LWC1 may be disposed on the first upper contact UPC1 and may be attached to the first upper contact UPC1. The first lower contact LWC1 may be disposed in a vertical direction (e.g., the Z direction) with respect to the first metal pattern 640. According to an example embodiment, the first lower contact LWC1 may include a contact pad 632 and a contact metal pattern 634. The contact pad 632 may be disposed on the contact pad 622 of the first upper contact UPC1. For example, one surface of the contact pad 632 may be in contact with the contact pad 622 of the first upper contact UPC1, and another surface of the contact pad 632 may be in contact with the contact metal pattern 634. The contact pad 632 may be formed of copper, but example embodiments are not limited thereto. The contact pad 632 may include a plurality of layers having different widths. A middle layer of the contact pad 632 may have a width that varies. The contact metal pattern 634 may be stacked on a first portion of the first metal pattern 640 in a direction toward the peripheral circuit region of the peripheral circuit structure PCS on the contact pad 632.

The first metal pattern 640 may extend at a first layer in the horizontal direction. Referring to FIG. 6, for example, the first metal pattern 640 may extend in the first horizontal direction (e.g., the Y direction), and two or more first metal pattern 640 may be arranged side by side in the second horizontal direction (e.g., the X direction). However, example embodiments are not limited thereto. The first lower contact LWC1 may be in contact with the first portion of the first metal pattern 640.

The via contact 650 may be disposed in a vertical direction (e.g., the Z direction) with respect to the first metal pattern 640. For example, the via contact 650 may be disposed in a second portion of the first metal pattern 640 that is different from the first portion of the first metal pattern 640 in contact with the first lower contact LWC1. The via contact 650 may extend in the vertical direction (e.g., the Z direction).

The third interlayer insulating layer 635 may be formed to cover the first metal pattern 640, the via contact 650, and a plurality of second metal patterns 660, 662, 664, 666, and 668. The third interlayer insulating layer 635 may be formed to fill a space between the first metal pattern 640, the via contact 650, and the plurality of second metal patterns 660, 662, 664, 666, and 668. For example, the third interlayer insulating layer 635 may cover an upper surface of the first metal pattern 640, a lateral surface of the via contact 650, respective lateral surfaces of the plurality of second metal patterns 660, 662, 664, 666, and 668, respective upper surfaces of the plurality of second metal patterns 660, 662, 664, 666, and 668, and respective lower surfaces of the plurality of second metal patterns 660, 662, 664, 666, and 668.

The at least one second metal pattern may extend in a different horizontal direction (second horizontal direction (e.g., the X direction)) from a horizontal direction (first horizontal direction (e.g., the Y direction) in which the first metal pattern 640 extends, at a second layer different from the first layer. For example, the second layer may be located in the third interlayer insulating layer 635 and above the first layer. There may be a plurality of second metal patterns as shown in FIG. 6, but the number of second metal patterns is not limited thereto. For example, the plurality of second metal patterns 660, 662, 664, 666, and 668 may each extend in the second horizontal direction (e.g., the X direction), and may be arranged side by side in the first horizontal direction (e.g., the Y direction). The second metal patterns 666 may be in contact with the via contact 650 at the second layer.

Although the second layer on the first layer has been explained with reference to FIGS. 5 and 6, example embodiments are not limited thereto, and the first layer may be provided on the second layer.

Referring to FIGS. 5, 6, and 7, a peripheral circuit region of a peripheral circuit structure PCS may include a substrate 710, a second circuit device 711, a first interlayer insulating layer 715, and a second upper contact UPC2. The substrate 710 and the first interlayer insulating layer 715 may be the same as the substrate 610 and the first interlayer insulating layer 615 of FIG. 6.

According to an example embodiment, the second circuit device 711 may be included in a first circuit of the peripheral circuit structure PCS. For example, the second circuit device 711 may be a transistor included in the column decoder C/D. Example embodiments are not limited thereto. According to other example embodiments, the second circuit device 711 may be included in a circuit that operates during a test operation.

The second upper contact UPC2 may be disposed on the second circuit device 711, and may be attached to a second lower contact LWC2. According to an example embodiment, the second upper contact UPC2 may include at least one contact metal pattern that is in contact with the second circuit device 711 and stacked in a direction toward the dummy region 520 (e.g., first, second, third, fourth, and fifth contact metal patterns 712, 714, 716, 718, and 720), and a contact pad 722. The contact pad 722 may be disposed on an uppermost contact metal pattern (e.g., the fifth contact metal pattern 720) included in the second upper contact UPC2. The contact pad 722 may be formed of copper, but example embodiments are not limited thereto. The contact pad 722 may include a plurality of layers having different widths. A middle layer of the contact pad 722 may have a width that varies.

The dummy region 520 may include the second lower contact LWC2, a plurality of first metal patterns 740, 742, 744, and 746, a via contact 750, a second interlayer insulating layer 725, a third interlayer insulating layer 735, and at least one second metal pattern 760.

The second lower contact LWC2 may be disposed on the second upper contact UPC2 and may be attached to the second upper contact UPC2. The second lower contact LWC2 may extend in a vertical direction (e.g., the Z direction) with respect to the second metal pattern 760. According to an example embodiment, the first lower contact LWC1 may include a contact pad 732 and at least one contact metal pattern (e.g., 734, 736, and/or 738). The contact pad 732 may be disposed on the contact pad 722 of the second upper contact UPC2. For example, one surface of the contact pad 732 may be in contact with the contact pad 722 of the second upper contact UPC2, and another surface of the contact pad 732 may be in contact with the contact metal pattern 734. The contact pad 732 may be formed of copper, but example embodiments are not limited thereto. The contact pad 732 may include a plurality of layers having different widths. A middle layer of the contact pad 732 may have a width that varies. The plurality of contact metal patterns 734, 736, and 738 may be stacked on a first portion of the second metal pattern 760 in a direction toward the peripheral circuit region of the peripheral circuit structure PCS on the contact pad 732.

The plurality of first metal patterns 740, 742, 744, and 746 may each extend in the first horizontal direction (e.g., the Y direction), and may be arranged side by side in the second horizontal direction (e.g., the X direction).

The via contact 750 may be disposed over one first metal pattern (e.g., 742) among the plurality of first metal patterns 740, 742, 744, and 746.

The second interlayer insulating layer 725 may be formed to cover the second lower contact LWC2, the plurality of first metal patterns 740, 742, 744, and 746, and the via contact 750.

At least one second metal pattern 760 may extend in the second horizontal direction (e.g., the X direction) at a second layer. The via contact 750 may be in contact with a portion of the at least one second metal pattern 760.

The third interlayer insulating layer 735 may be formed to cover upper and lateral surfaces of the at least one second metal pattern 760.

According to an example embodiment, respective resistances of the first and second metal patterns may be the same as each other. Referring to FIG. 6, for example, respective resistances of the first metal pattern 640 and the second metal pattern 666 may be the same as each other. Referring to FIG. 7, for example, respective resistances of the first metal pattern 742 and the second metal pattern 760 may be the same as each other. According to example embodiments, first and second metal patterns may be formed of a material with a relatively high resistance (e.g., tungsten). A signal SIG between the first circuit device 611 and the second circuit device 711 may be transmitted through a first metal pattern (e.g., 640 or 742), a via contact (e.g., 650 or 750), and a second metal pattern (e.g., 666 or 760).

As discussed above, by disposing at least some wiring of the peripheral circuit structure PCS in each of different layers of the dummy region 520 of the cell array structure CAS, the integration degree of the memory device 500 within limited resources is increased.

As the complexity of the wiring for a peripheral circuit within the peripheral circuit structure PCS increases, designing a power network via which a supply voltage to be provided to the peripheral circuit is generated may become more complicated. The power network may be composed of power lines to which the supply voltage is applied, wherein the power lines are arranged in a mesh-type form. Accordingly, for resource efficiency, the power network may be placed in the dummy region 520 of the cell array structure CAS to increase integration degree.

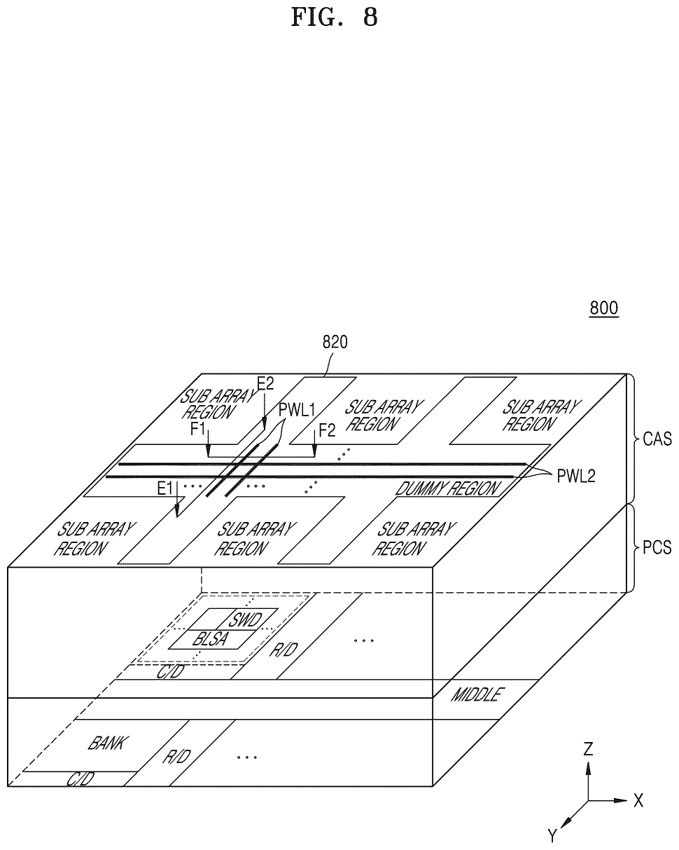

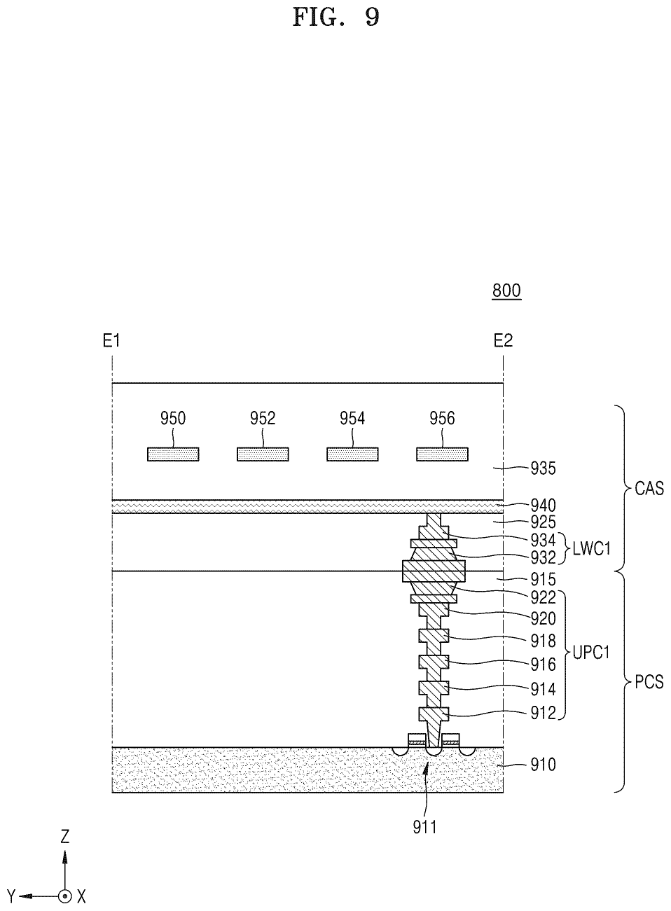

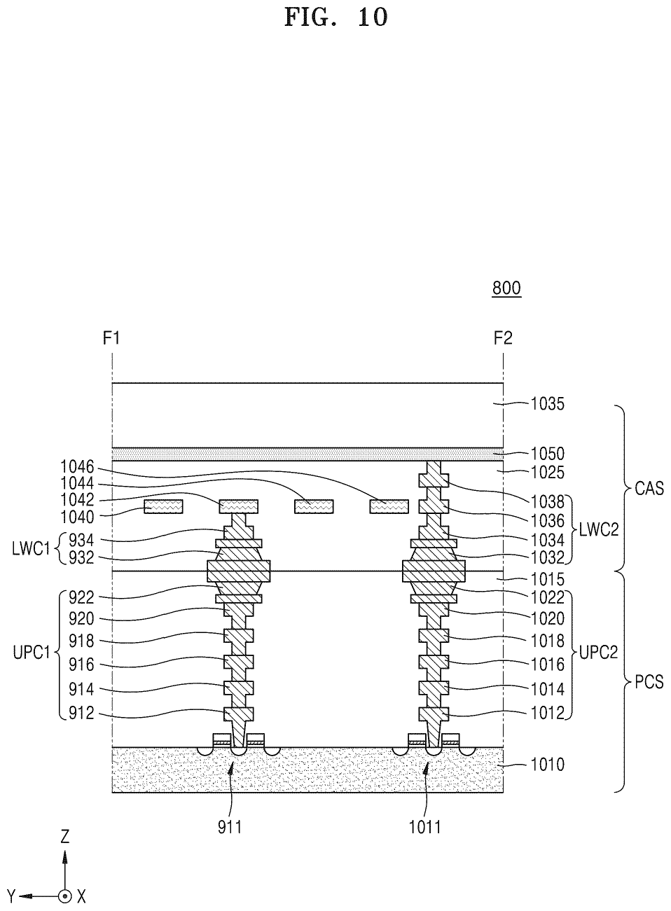

FIG. 8 is a view for explaining a power network according to example embodiments. FIG. 9 is a cross-sectional view of a memory device taken along line E1-E2 of FIG. 8. FIG. 10 is a cross-sectional view of the memory device taken along line F1-F2 of FIG. 8.

Referring to FIG. 8, the power network may be formed in a dummy region 820. First power lines PWL1 of the power network may each extend in the first horizontal direction (e.g., the Y direction) and may be arranged side by side in the second horizontal direction (e.g., the X direction). Second power lines PWL2 of the power network may each extend in the second horizontal direction (e.g., the X direction) and may be arranged side by side in the first horizontal direction (e.g., the Y direction).

According to an example embodiment, the power network may be formed in a portion of the dummy region 820. Referring to FIG. 8, for example, the first power lines PWL1 and the second power lines PWL2 may be arranged only in an area having the same horizontal coordinates (e.g., coordinates in the X direction and the Y direction) as the middle region MIDDLE of the peripheral circuit structure PCS, among the areas of the dummy region 820. The first power lines PWL1 and the second power lines PWL2 may not be arranged in areas that have horizontal coordinates different from the horizontal coordinates of the middle region MIDDLE, among the areas of the dummy region 820. However, example embodiments are not limited thereto. According to other example embodiments, the power network may be formed in the entirety of the dummy region 820. The power network may be connected to the peripheral circuit structure PCS so that voltages generated by a voltage generation circuit (e.g., a high voltage, a negative voltage, a bit line precharge voltage, and an internal power supply voltage) may be transmitted to the peripheral circuit through the power network.

Referring to FIGS. 8 and 9, a peripheral circuit region of a peripheral circuit structure PCS may include a substrate 910, a first power circuit device 911, a first interlayer insulating layer 915, and a first upper contact UPC1. The substrate 910 and the first interlayer insulating layer 915 may be the same as the substrate and the first interlayer insulating layer described above with reference to FIGS. 2, 4, and 6.

The first power circuit device 911 may be connected to the first upper contact UPC1. The first power circuit device 911 may be included in the voltage generation circuit. According to an example embodiment, the first power circuit device 911 may control transmission of a first supply voltage. For example, when the first power circuit device 911 is turned on, the first supply voltage may be applied to a first power metal pattern 940.

The first upper contact UPC1 may be disposed on the first power circuit device 911, and may be attached to a first lower contact LWC1. According to an example embodiment, the first upper contact UPC1 may include at least one contact metal pattern and a contact pad 922. The at least one contact metal pattern may be in contact with the first power circuit device 911 and stacked in a direction toward the dummy region 820. One surface of the contact pad 922 may be in contact with the at least one contact metal pattern, and another surface of the contact pad 922 may be in contact with a contact pad 932 of the first lower contact LWC1. For example, the first upper contact UPC1 may include first, second, third, fourth, and fifth contact metal patterns 912, 914, 916, 918, and 920 and the contact pad 922. The contact pad 922 may be formed of copper, but example embodiments are not limited thereto. The contact pad 922 may include a plurality of layers having different widths. A middle layer of the contact pad 922 may have a width that varies.

The dummy region 820 may include a second interlayer insulating layer 925, the first lower contact LWC1, at least one first power metal pattern 940, at least one second power metal pattern (e.g., 950, 952, 954, and/or 956), and a third interlayer insulating layer 935.

The second interlayer insulating layer 925 may be formed to cover a lateral surface of the first lower contact LWC1 and lower and lateral surfaces of the first power metal pattern 940.

The first lower contact LWC1 may be disposed in a vertical direction (e.g., the Z direction) with respect to the first power metal pattern 940. The first lower contact LWC1 may be disposed on the first upper contact UPC1 and may be attached to the first upper contact UPC1. According to an example embodiment, the first lower contact LWC1 may include a contact pad 932 and a contact metal pattern 934. One surface of the contact pad 932 may be in contact with the contact metal pattern 934, and another surface of the contact pad 932 may be in contact with a contact pad 922 of the first upper contact UPC1. The contact pad 932 may include a plurality of layers having different widths. A middle layer of the contact pad 932 may have a width that varies. The contact metal pattern 934 may be stacked on the first power metal pattern 940 in a direction toward the peripheral circuit region of the peripheral circuit structure PCS.

The at least one first power metal pattern 940 may extend in the horizontal direction at a first layer. Referring to FIG. 6, for example, at least one first power metal pattern 940 may extend in the first horizontal direction (e.g., the Y direction), and two or more first power metal patterns 940 may be arranged side by side in the second horizontal direction (e.g., the X direction). However, example embodiments are not limited thereto.

A plurality of second power metal patterns 950, 952, 954, and 956 may each extend in the second horizontal direction (e.g., the X direction) at a second layer different from the first layer, and may be arranged side by side in the first horizontal direction (e.g., the Y direction).

The third interlayer insulating layer 935 may be formed to cover upper and lateral surfaces of the at least one first power metal pattern 940 and the plurality of second power metal patterns 950, 952, 954, and 956 and fill a space between the plurality of second power metal patterns 950, 952, 954, and 956.

Referring to FIGS. 8, 9, and 10, the peripheral circuit region of the peripheral circuit structure PCS may include a substrate 1010, a second power circuit device 1011, a first interlayer insulating layer 1015, and a second upper contact UPC2. The substrate 1010 and the first interlayer insulating layer 1015 may be the same as the substrate and the first interlayer insulating layer described above.

The second power circuit device 1011 may be connected to the second upper contact UPC2. The second power circuit device 1011 may be included in the voltage generation circuit. According to an example embodiment, the second power circuit device 1011 may control transmission of a second supply voltage. For example, when the second power circuit device 1011 is turned on, the second supply voltage may be applied to at least one second power metal pattern 1050. According to an example embodiment, a voltage level of the first supply voltage may be higher than that of the second supply voltage. For example, the first supply voltage may correspond to a power supply voltage (e.g., VDD), and the second supply voltage may correspond to a ground voltage. However, example embodiments are not limited thereto.

The second upper contact UPC2 may be disposed on the second power circuit device 1011, and may be attached to a second lower contact LWC2. According to an example embodiment, the second upper contact UPC2 may include at least one contact metal pattern that is in contact with the second power circuit device 1011 and stacked in a direction toward the dummy region 820 (e.g., first, second, third, fourth, and fifth contact metal patterns 1012, 1014, 1016, 1018, and 1020), and a contact pad 1022. The contact pad 1022 may be disposed on an uppermost contact metal pattern (e.g., the fifth contact metal pattern 1020) included in the second upper contact UPC2. The contact pad 1022 may be formed of copper, but example embodiments are not limited thereto. The contact pad 1022 may include a plurality of layers having different widths. A middle layer of the contact pad 1022 may have a width that varies.

The second lower contact LWC2 may be disposed on the second upper contact UPC2 and may be attached to the second upper contact UPC2. The second lower contact LWC2 may extend in a vertical direction (e.g., the Z direction) with respect to the second power metal pattern 1050. According to an example embodiment, the second lower contact LWC2 may include a contact pad 1032 and at least one contact metal pattern (e.g., 1034, 1036, and/or 1038). The contact pad 1032 may be disposed on the contact pad 1022 of the second upper contact UPC2. The contact pad 1032 may be formed of copper, but example embodiments are not limited thereto. The contact pad 1032 may include a plurality of layers having different widths. A middle layer of the contact pad 1032 may have a width that varies. A plurality of contact metal patterns 1034, 1036, and 1038 may be disposed on the contact pad 1032, and may be stacked on the second power metal pattern 1050 in a direction toward the peripheral circuit region of the peripheral circuit structure PCS.

A plurality of first power metal patterns 1040, 1042, 1044, and 1046 may each extend in the first horizontal direction (e.g., the Y direction), and may be arranged side by side in the second horizontal direction (e.g., the X direction).

A second interlayer insulating layer 1025 may be formed to cover the first lower contact LWC1, the second lower contact LWC2, the plurality of first power metal patterns 1040, 1042, 1044, and 1046. The second interlayer insulating layer 1025 may be formed to further cover the at least one second metal pattern 760 of FIG. 7.

At least one second power metal pattern 1050 may extend in the second horizontal direction (e.g., the X direction) at the second layer. Because the first layer and the second layer exemplarily show relative positions in the vertical direction (e.g., the Z direction), the second layer of the present disclosure may be located above the first layer of the present disclosure.

The third interlayer insulating layer 1035 may be formed to cover upper and lateral surfaces of the at least one second metal pattern 760 of FIG. 7.

According to an example embodiment, respective resistances of the first and second power metal patterns may be the same as each other. A voltage level of a first supply voltage applied to the first power metal pattern may be different from that of a second supply voltage applied to the second power metal pattern.

As discussed above, by disposing the power network in each of different layers of the dummy region 820 of the cell array structure CAS, the integration degree of the memory device 800 within limited resources is increased.

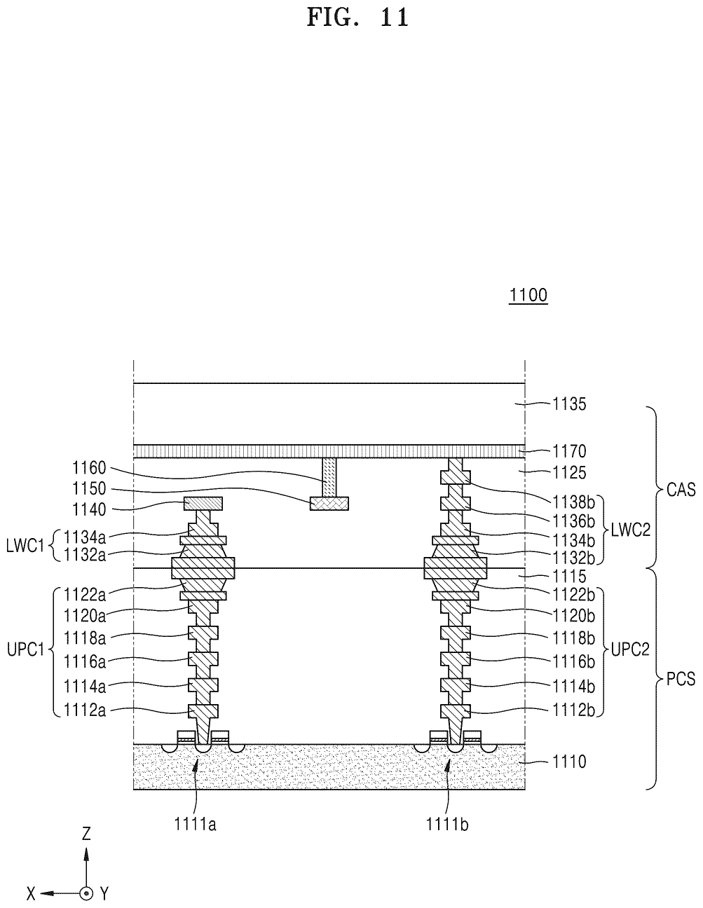

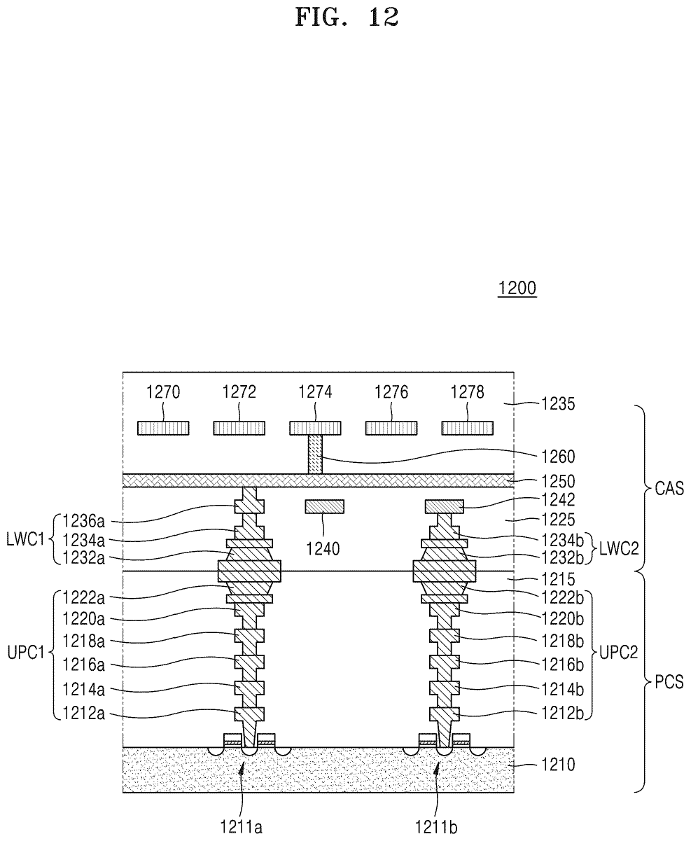

FIGS. 11 and 12 are cross-sectional views of semiconductor devices according to an example embodiment. In detail, FIG. 11 is a cross-sectional view of a memory device 1100 cut along a line extending in one horizontal direction, and FIG. 12 is a cross-sectional view of a memory device 1200 cut along a line extending in a horizontal direction different from that of FIG. 11.

Referring to FIG. 11, the memory device 1100 may include a cell array structure CAS and a peripheral circuit structure PCS. A peripheral circuit region of the peripheral circuit structure PCS may include a substrate 1110, a first circuit device 1111a, a second circuit device 1111b, a first interlayer insulating layer 1115, a first upper contact UPC1, and a second upper contact UPC2.

The substrate 1110 and the first interlayer insulating layer 1115 may be the same as the substrate and the first interlayer insulating layer described above. According to an example embodiment, the first circuit device 1111a may be included in a first circuit, and the second circuit device 1111b may be included in a second circuit. According to other example embodiments, the first circuit device 1111a may be included in the first circuit, and the second circuit device 1111b may be included as a test circuit device in a test circuit.

The first upper contact UPC1 may be disposed on the first circuit device 111a, and may be attached to a first lower contact LWC1. According to an example embodiment, the first upper contact UPC1 may include at least one contact metal pattern, for example, first, second, third, fourth, and fifth contact metal patterns 1112a, 1114a, 1116a, 1118a, and 1120a. The first upper contact UPC1 may further include a contact pad 1122a. The contact pad 1122a may include a plurality of layers having different widths. A middle layer of the contact pad 1122a may have a width that varies. The second upper contact UPC2 may be disposed on the second circuit device 1111b, and may be attached to a second lower contact LWC2. According to an example embodiment, the second upper contact UPC2 may include at least one contact metal pattern, for example, first, second, third, fourth, and fifth contact metal patterns 1112b, 1114b, 1116b, 1118b, and 1120b. The second upper contact UPC2 may further include a contact pad 1122b. The contact pad 1122a and the contact pad 1122b may be formed of copper, but example embodiments are not limited thereto.

A dummy region of the cell array structure CAS may include a second interlayer insulating layer 1125, the first lower contact LWC1, the second lower contact LWC2, a first metal pattern 1140, a second metal pattern 1150, a via contact 1160, a third metal pattern 1170, and a third interlayer insulating layer 1135.

The second interlayer insulating layer 1125 may be formed to cover the first lower contact LWC1, the second lower contact LWC2, the first metal pattern 1140, the second metal pattern 1150, the via contact 1160, and the third metal pattern 1170. The second interlayer insulating layer 1125 may be formed to fill a space between the first lower contact LWC1, the second lower contact LWC2, the first metal pattern 1140, the second metal pattern 1150, the via contact 1160, and the third metal pattern 1170.

The first lower contact LWC1 may include a contact pad 1132a attached to the contact pad 1122a of the first upper contact UPC1 on the peripheral circuit structure PCS, and a contact metal pattern 1134a stacked on the first metal pattern 1140 in a direction toward the peripheral circuit structure PCS. The contact pad 1132a may include a plurality of layers having different widths. A middle layer of the contact pad 1132a may have a width that varies.

The second lower contact LWC2 may include a contact pad 1132b attached to the contact pad 1122b of the second upper contact UPC2 on the peripheral circuit structure PCS, and a plurality of contact metal patterns 1134b, 1136b, and 1138b stacked on the third metal pattern 1170 in a direction toward the peripheral circuit structure PCS. The contact pads 1132b and 1122b may each include a plurality of layers having different widths. A middle layer of the contact pads 1132b and 1122b may have a width that varies.

The first metal pattern 1140 and the second metal pattern 1150 may each extend in the first horizontal direction (e.g., the Y direction) at a first layer, and may be arranged side by side in the second horizontal direction (e.g., the X direction). However, example embodiments are not limited thereto. Each of the first metal pattern 1140 and the second metal pattern 1150 may include a plurality of patterns. The via contact 1160 may be disposed in the vertical direction (e.g., the Z direction) on the second metal pattern 1150. The third metal pattern 1170 may contact the via contact 1160 at a layer (e.g., a second layer) different from the first layer, and may extend in the second horizontal direction (e.g., the X direction).

According to an example embodiment, the first metal pattern 1140 may correspond to the first metal pattern 440, the second metal pattern 1150 may correspond to the first metal pattern 640 (and/or any one of the plurality of first metal patterns 740, 742, 744, and 746), the via contact 1160 may correspond to the via contact 650 (and/or the via contact 750), and the third metal pattern 1170 may correspond to any one of the plurality of second metal patterns 660, 662, 664, 666, and 668 (and/or the second metal patterns 760).

According to an example embodiment, a resistance of the first metal pattern 1140 may be less than that of at least one of the second metal pattern 1150 and the third metal pattern 1170. For example, the first metal pattern 1140 may be formed of copper, and the second metal pattern 1150 and the third metal pattern 1170 may be formed of tungsten, but example embodiments are not limited thereto.

The third interlayer insulating layer 1135 may be formed to cover an upper surface of the third metal pattern 1170.

Referring to FIG. 12, the memory device 1200 may include a cell array structure CAS and a peripheral circuit structure PCS. A peripheral circuit region of the peripheral circuit structure PCS may include a substrate 1210, a first circuit device 1211a, a second circuit device 1211b, a first interlayer insulating layer 1215, a first upper contact UPC1, and a second upper contact UPC2. The substrate 1210, the first interlayer insulating layer 1215, the first upper contact UPC1, and the second upper contact UPC2 may be the same as the substrate, the first interlayer insulating layer, the first upper contact, and the second upper contact described above. According to an example embodiment, the first circuit device 1211a may be included in a third circuit, and the second circuit device 1211b may be included in a fourth circuit. According to other example embodiments, the first circuit device 1211a may be included as a test circuit device in a test circuit, and the second circuit device 1211b may be included in a fourth circuit.

A dummy region of the cell array structure CAS may include a second interlayer insulating layer 1225, a first lower contact LWC1, a second lower contact LWC2, a plurality of first metal patterns 1240 and 1242, a second metal pattern 1250, a via contact 1260, a plurality of third metal patterns 1270, 1272, 1274, 1276, and 1278, and a third interlayer insulating layer 1235. Similar to the cell array structure CAS of FIG. 11, the second interlayer insulating layer 1225, the first lower contact LWC1, the second lower contact LWC2, and the plurality of first metal patterns 1240 and 1242 may be formed. Unlike the cell array structure CAS of FIG. 11, the second metal pattern 1250 in the cell array structure CAS of FIG. 12 may be disposed at a different layer from respective locations of the plurality of first metal patterns 1240 and 1242. For example, the plurality of first metal patterns 1240 and 1242 may be disposed at the first layer, and the second metal pattern 1250 may be disposed at the second layer. The via contact 1260 may be arranged on one third metal pattern (e.g., 1274) among the plurality of third metal patterns 1270, 1272, 1274, 1276, and 1278 in a vertical direction. The plurality of third metal patterns 1270, 1272, 1274, 1276, and 1278 may be arranged at a third layer that is different from the first layer and the second layer. The plurality of third metal patterns 1270, 1272, 1274, 1276, and 1278 may each extend in the same horizontal direction as the plurality of first metal patterns 1240 and 1242, and may be arranged in the same horizontal direction as the plurality of first metal patterns 1240 and 1242.

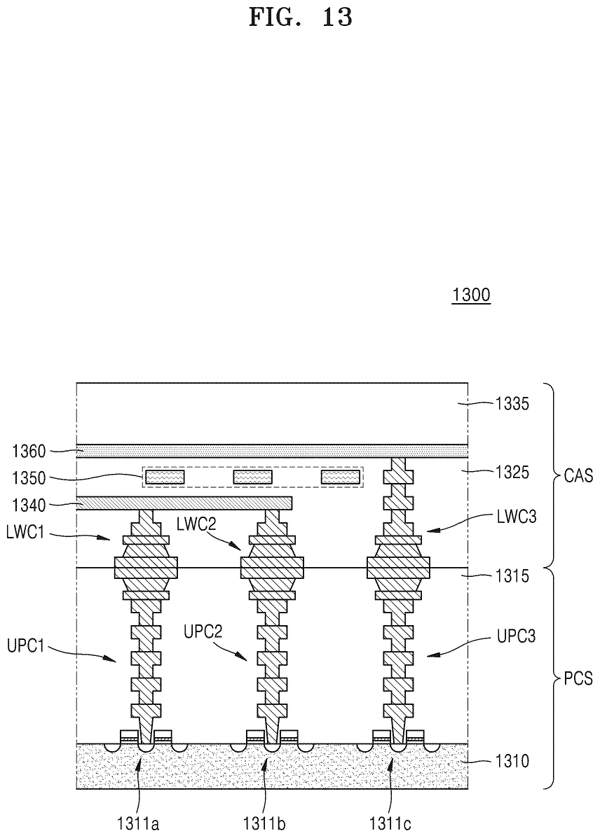

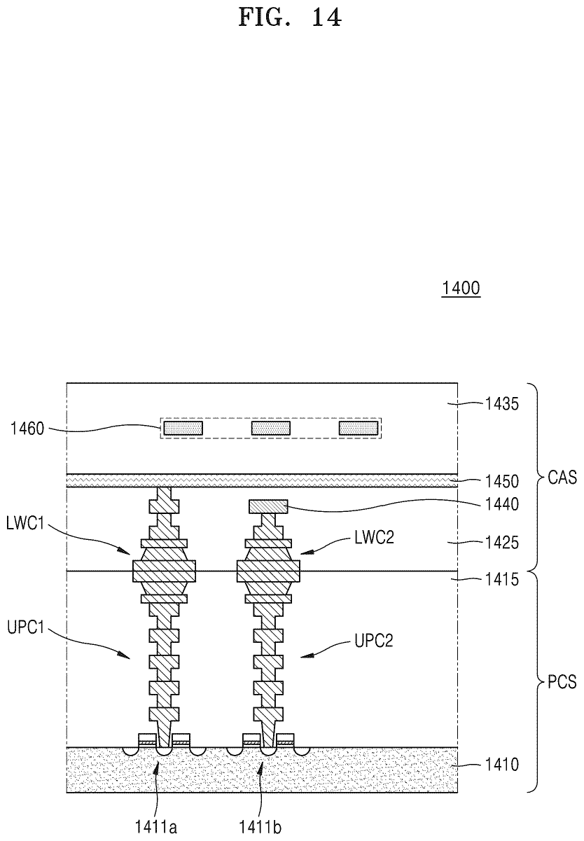

FIGS. 13 and 14 are cross-sectional views of other semiconductor devices according to other example embodiments. In detail, FIG. 13 is a cross-sectional view of a memory device 1300 cut along a line extending in one horizontal direction, and FIG. 14 is a cross-sectional view of a memory device 1400 cut along a line extending in a horizontal direction different from the one horizontal direction.

Referring to FIG. 13, the memory device 1300 may include a cell array structure CAS and a peripheral circuit structure PCS. A peripheral circuit region of the peripheral circuit structure PCS may include a substrate 1310, a first circuit device 1311a, a second circuit device 1311b, a third circuit device 1311c, a first interlayer insulating layer 1315, a first upper contact UPC1, a second upper contact UPC2, and a third upper contact UPC3. The substrate 1310 may be the same as the substrate described above. According to an example embodiment, the first circuit device 1311a may be included in a first circuit, the second circuit device 1311b may be included in a second circuit, and the third circuit device 1311c may be included as a power circuit device in a voltage generation circuit. However, example embodiments are not limited thereto. The first interlayer insulating layer 1315 may be formed to cover the first upper contact UPC1, the second upper contact UPC2, and the third upper contact UPC3. Each of the first upper contact UPC1, the second upper contact UPC2, and the third upper contact UPC3 may each be disposed vertically on the substrate 1310, and may be arranged side by side in the horizontal direction.

A dummy region of the cell array structure CAS may include a second interlayer insulating layer 1325, a first lower contact LWC1, a second lower contact LWC2, a third lower contact LWC3, a first metal pattern 1340, a first power metal pattern 1350, a second power metal pattern 1360, and a third interlayer insulating layer 1335. The first lower contact LWC1, the second lower contact LWC2, and the first metal pattern 1340 may be the same as those described above with reference to FIG. 4. The first power metal pattern 1350 and the second power metal pattern 1360 may be the same as those described above with reference to FIGS. 8, 9, and 10. The third lower contact LWC3 may be connected to the third upper contact UPC3 through a pad. The second power metal pattern 1360 may be in contact with an uppermost layer of the third lower contact LWC3. According to an example embodiment, the first metal pattern 1340 may be disposed in a first layer, the first power metal pattern 1350 may be disposed in a second layer, and the second power metal pattern 1360 may be disposed in a third layer.

Referring to FIG. 14, the memory device 1400 may include a cell array structure CAS and a peripheral circuit structure PCS. A peripheral circuit region of the peripheral circuit structure PCS may include a substrate 1410, a first circuit device 1411a, a second circuit device 1411b, a first interlayer insulating layer 1415, a first upper contact UPC1, and a second upper contact UPC2. The substrate 1410 may be the same as the substrate described above. According to an example embodiment, the first circuit device 1411a may be included as a power circuit device in a voltage generation circuit, and the second circuit device 1411b may be included in a third circuit. However, example embodiments are not limited thereto. The first interlayer insulating layer 1415 may be formed to cover the first upper contact UPC1 and the second upper contact UPC2.

A dummy region of the cell array structure CAS may include a second interlayer insulating layer 1425, a first lower contact LWC1, a second lower contact LWC2, a first metal pattern 1440, a first power metal pattern 1450, a second power metal pattern 1460, and a third interlayer insulating layer 1435. The first lower contact LWC1, the second lower contact LWC2, and the first metal pattern 1440 may be the same as those described above with reference to FIG. 4. The first power metal pattern 1450 and the second power metal pattern 1460 may be the same as those described above with reference to FIGS. 8, 9, and 10. According to an example embodiment, the first metal pattern 1440 may be disposed in a first layer, the first power metal pattern 1450 may be disposed in a second layer, and the second power metal pattern 1460 may be disposed in a third layer.

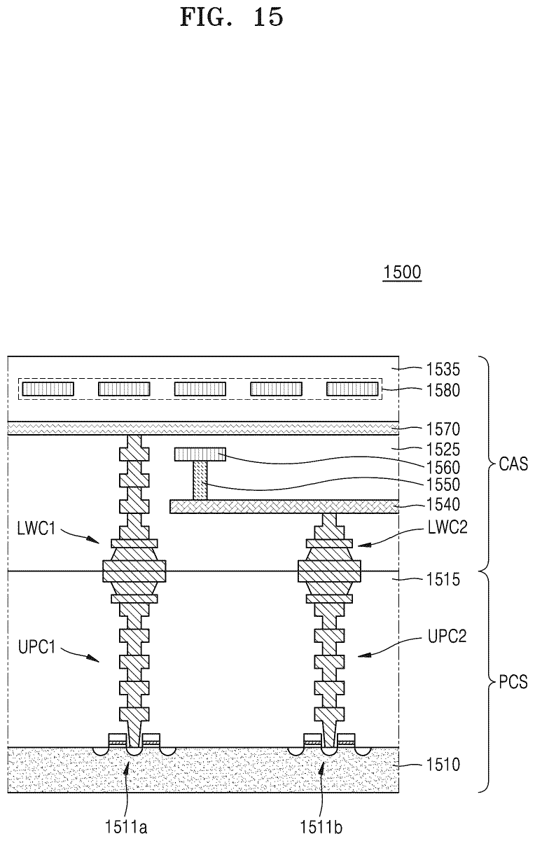

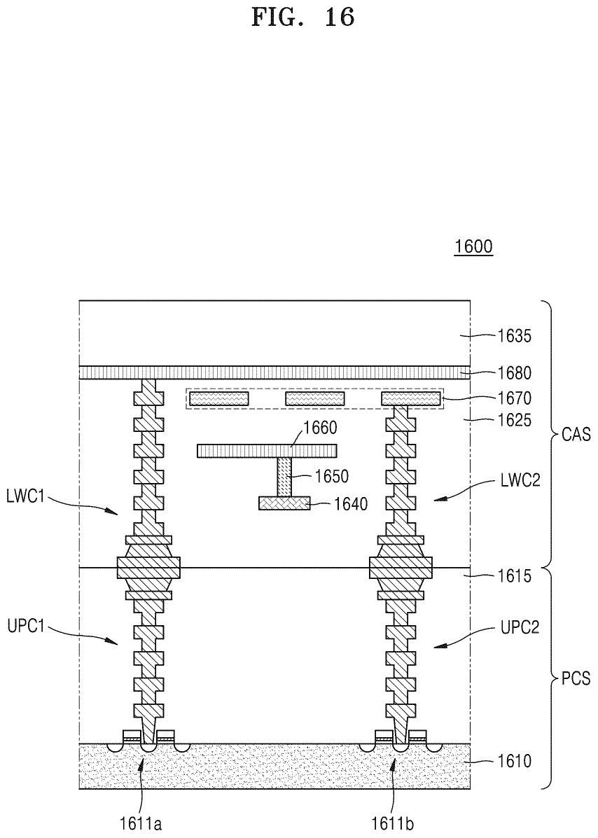

FIGS. 15 and 16 are cross-sectional views of semiconductor devices according to other example embodiments. In detail, FIG. 15 is a cross-sectional view of a memory device 1500 cut along a line extending in one horizontal direction, and FIG. 16 is a cross-sectional view of a memory device 1600 cut along a line extending in a horizontal direction different from the one horizontal direction. The same description as described above will be omitted.

Referring to FIG. 15, the memory device 1500 may include a cell array structure CAS and a peripheral circuit structure PCS. A peripheral circuit region of the peripheral circuit structure PCS may include a substrate 1510, a first circuit device 1511a, a second circuit device 1511b, a first interlayer insulating layer 1515, a first upper contact UPC1, and a second upper contact UPC2. According to an example embodiment, the first circuit device 1511a may be included as a test circuit device in a test circuit. However, example embodiments are not limited thereto. According to an example embodiment, the second circuit device 1511b may be included as a power circuit device in a voltage generation circuit. According to other example embodiments, the second circuit device 1511b may be included in a first circuit. However, example embodiments are not limited thereto.

A dummy region of the cell array structure CAS may include a second interlayer insulating layer 1525, a first lower contact LWC1, a second lower contact LWC2, a first metal pattern 1540, a via contact 1550, a second metal pattern 1560, a first power metal pattern 1570, a second power metal pattern 1580, and a third interlayer insulating layer 1535. The first lower contact LWC1 may be in contact with the first upper contact UPC1 and may be in contact with the first power metal pattern 1570. The second lower contact LWC2 may be in contact with the second upper contact UPC2 and may be in contact with the first metal pattern 1540. The first metal pattern 1540 may be the same as that described above with reference to FIGS. 5, 6, and 7. The via contact 1550 may be arranged in a vertical direction on the first metal pattern 1540 and contact the first metal pattern 1540 and the second metal pattern 1560. According to an example embodiment, the first metal pattern 1540 may be disposed in a first layer, the second metal pattern 1560 may be disposed in a second layer, the first power metal pattern 1570 may be disposed in a third layer, and the second power metal pattern 1580 may be disposed in a fourth layer. According to an example embodiment, the first metal pattern 1540 and the second metal pattern 1560 may have the same resistances. For example, the first metal pattern 1540 and the second metal pattern 1560 may be formed of tungsten, but example embodiments are not limited thereto.

Referring to FIG. 16, the memory device 1600 may include a cell array structure CAS and a peripheral circuit structure PCS. A peripheral circuit region of the peripheral circuit structure PCS may include a substrate 1610, a first circuit device 1611a, a second circuit device 1611b, a first interlayer insulating layer 1615, a first upper contact UPC1, and a second upper contact UPC2. According to an example embodiment, the first circuit device 1611a may be included as a power circuit device in a voltage generation circuit. However, example embodiments are not limited thereto. The second circuit device 1611b may be included as a power circuit device in a voltage generation circuit. However, example embodiments are not limited thereto.

A dummy region of the cell array structure CAS may include a second interlayer insulating layer 1625, a first lower contact LWC1, a second lower contact LWC2, a first metal pattern 1640, a via contact 1650, a second metal pattern 1660, a first power metal pattern 1670, a second power metal pattern 1680, and a third interlayer insulating layer 1635. According to an example embodiment, the first metal pattern 1640, the second metal pattern 1660, the first power metal pattern 1670, and the second power metal pattern 1680 may be disposed in different layers. According to an example embodiment, the first metal pattern 1640 and the second metal pattern 1660 may have the same resistances.

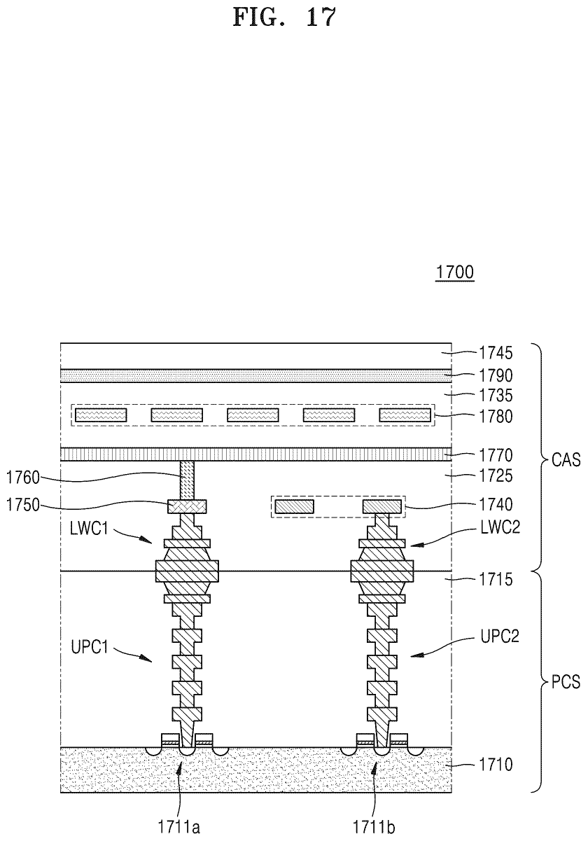

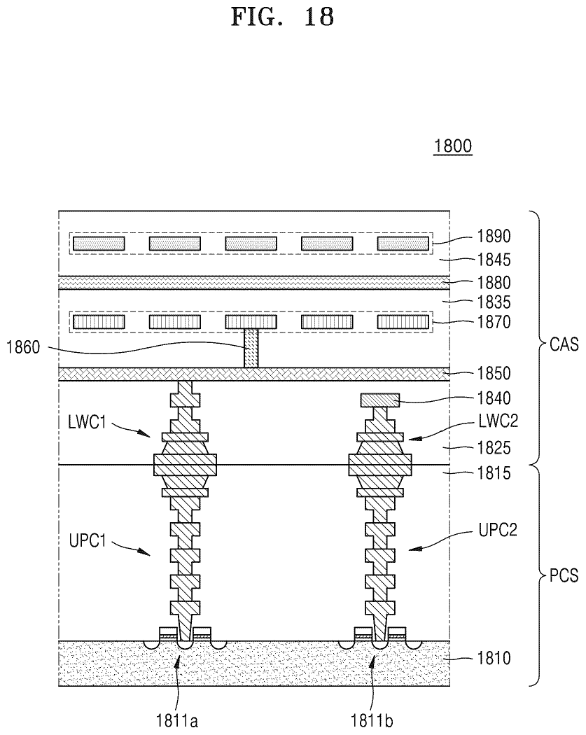

FIGS. 17 and 18 are cross-sectional views of semiconductor devices according to other example embodiments. The same description as described above will be omitted.

Referring to FIG. 17, a memory device 1700 may include a cell array structure CAS and a peripheral circuit structure PCS. A peripheral circuit region of the peripheral circuit structure PCS may include a substrate 1710, a first circuit device 1711a, a second circuit device 1711b, a first interlayer insulating layer 1715, a first upper contact UPC1, and a second upper contact UPC2. A dummy region of the cell array structure CAS may include a second interlayer insulating layer 1725, a first lower contact LWC1, a second lower contact LWC2, a first metal pattern 1740, a second metal pattern 1750, a via contact 1760, a third metal pattern 1770, a first power metal pattern 1780, a second power metal pattern 1790, a third interlayer insulating layer 1735, and a fourth interlayer insulating layer 1745. According to an example embodiment, the first metal pattern 1740 and the second metal pattern 1750 may be disposed in the same layer, the first metal pattern 1740 and the third metal pattern 1770 may be disposed in different layers, the second metal pattern 1750 and the third metal pattern 1770 may be disposed in different layers, and the first power metal pattern 1780 and the second power metal pattern 1790 may be disposed in different layers. According to an example embodiment, a resistance of the first metal pattern 1740 may be less than that of at least one of the second metal pattern 1750 and the third metal pattern 1770. For example, the first metal pattern 1740 may be formed of copper, and the second metal pattern 1750 and the third metal pattern 1770 may be formed of tungsten, but example embodiments are not limited thereto.

Referring to FIG. 18, a memory device 1800 may include a cell array structure CAS and a peripheral circuit structure PCS. A peripheral circuit region of the peripheral circuit structure PCS may include a substrate 1810, a first circuit device 1811a, a second circuit device 1811b, a first interlayer insulating layer 1815, a first upper contact UPC1, and a second upper contact UPC2. A dummy region of the cell array structure CAS may include a second interlayer insulating layer 1825, a first lower contact LWC1, a second lower contact LWC2, a first metal pattern 1840, a second metal pattern 1850, a via contact 1860, a third metal pattern 1870, a first power metal pattern 1880, a second power metal pattern 1890, a third interlayer insulating layer 1835, and a fourth interlayer insulating layer 1845. According to an example embodiment, the first metal pattern 1840, the second metal pattern 1850, the third metal pattern 1870, the first power metal pattern 1880, and the second power metal pattern 1890 may be disposed in different layers. According to an example embodiment, a resistance of the first metal pattern 1840 may be less than that of at least one of the second metal pattern 1850 and the third metal pattern 1870.

It will be appreciated that the structure of the present disclosure can be modified or changed in various ways without departing from the scope or technical spirit of the present disclosure. In view of the foregoing, when changes and modifications of the present disclosure fall within the scope of the following claims and equivalents, the present disclosure is considered as including these changes and modifications of the present disclosure.

The present disclosure has been particularly shown and described with reference to example embodiments thereof. The terminology used herein is for the purpose of describing exemplary embodiments only and is not intended to be limiting of the present disclosure. Therefore, it will be understood by those skilled in the art that various changes in form and details may be made therein without departing from the spirit and scope of the present disclosure as defined by the appended claims.

1. A memory device comprising:
a plurality of sub-array regions arranged spaced apart in a first horizontal direction and a second horizontal direction, and each sub-array region comprising a plurality of memory cells, the first horizontal direction crossing the second horizontal direction;
a dummy region disposed between the plurality of sub-array regions, the dummy region comprising a first metal pattern extending in the first horizontal direction at a first layer, a first lower contact extending in a vertical direction on a first portion of the first metal pattern, and a second lower contact extending in the vertical direction on a second portion of the first metal pattern; and
a peripheral circuit region comprising a first upper contact connected to the first lower contact, a first circuit connected to the first upper contact, a second upper contact connected to the second lower contact, and a second circuit connected to the second upper contact.

2. The memory device of claim 1, wherein the dummy region further comprises:
a second metal pattern adjacent the first metal pattern and extending in the first horizontal direction;
a first via contact disposed on the second metal pattern and extending in the vertical direction;
a third metal pattern in contact with the first via contact at a second layer and extending in the second horizontal direction;
a third lower contact disposed on the second metal pattern and extending in the vertical direction; and
a fourth lower contact disposed on the third metal pattern and extending in the vertical direction, and
wherein the peripheral circuit region further comprises:
a third upper contact connected to the third lower contact;
a third circuit connected to the third upper contact;
a fourth upper contact connected to the fourth lower contact; and
a fourth circuit connected to the fourth upper contact.

3. The memory device of claim 2, wherein a resistance of the first metal pattern is less than a resistance of at least one of the second metal pattern and the third metal pattern.

4. The memory device of claim 1, wherein the dummy region further comprises:
a fourth metal pattern extending in the first horizontal direction at a second layer;
a second via contact disposed on the fourth metal pattern and extending in the vertical direction;
a fifth metal pattern in contact with the second via contact at a third layer, and extending in the second horizontal direction;
a fifth lower contact disposed on the fourth metal pattern and extending in the vertical direction; and
a sixth lower contact disposed on the fifth metal pattern and extending in the vertical direction, and
wherein the peripheral circuit region further comprises:
a fifth upper contact connected to the fifth lower contact;
a first test circuit connected to the fifth upper contact;
a sixth upper contact connected to the sixth lower contact; and
a second test circuit connected to the sixth upper contact.

5. The memory device of claim 4, wherein a resistance of the first metal pattern is less than a resistance of at least one of the fourth metal pattern and the fifth metal pattern.

6. The memory device of claim 1, wherein the dummy region further comprises:
a first power metal pattern extending in the first horizontal direction at a second layer;
a seventh lower contact disposed on the first power metal pattern and extending in the vertical direction;
a second power metal pattern extending in the second horizontal direction at a third layer; and
an eighth lower contact disposed on the second power metal pattern and extending in the vertical direction, and
wherein the peripheral circuit region further comprises:
a seventh upper contact connected to the seventh lower contact;
a first power circuit connected to the seventh upper contact;
an eighth upper contact connected to the eighth lower contact; and
a second power circuit connected to the eighth upper contact.

7. The memory device of claim 1, wherein the first lower contact comprises:
a first contact metal pattern disposed on the first portion of the first metal pattern and extending toward the peripheral circuit region; and
a first contact pad disposed between the first contact metal pattern and the first upper contact, and
wherein the second lower contact comprises:
a second contact metal pattern disposed on the second portion of the first metal pattern and extending toward the peripheral circuit region; and
a second contact pad disposed between the second contact metal pattern and the second upper contact.

8. The memory device of claim 7, wherein the first upper contact comprises:
at least one third contact metal pattern in contact with the first circuit and extending toward the dummy region; and
a third contact pad disposed between the at least one third contact metal pattern and the first contact pad, and
wherein the second upper contact comprises:
at least one fourth contact metal pattern in contact with the second circuit and extending toward the dummy region; and
a fourth contact pad disposed between the at least one fourth contact metal pattern and the second contact pad.

9. A memory device comprising:
a plurality of sub-array regions each comprising a plurality of memory cells;
a dummy region adjacent the plurality of sub-array regions, the dummy region comprising a first power metal pattern extending in a first horizontal direction at a first layer, a first lower contact extending in a vertical direction on the first power metal pattern, a second power metal pattern extending in a second horizontal direction at a second layer, and a second lower contact extending in the vertical direction on the second power metal pattern; and
a peripheral circuit region comprising a first upper contact connected to the first lower contact, a first power circuit connected to the first upper contact, a second upper contact connected to the second lower contact, and a second power circuit connected to the second upper contact.

10. The memory device of claim 9, wherein the dummy region further comprises:
a first metal pattern extending in one of the first horizontal direction and the second horizontal direction at a third layer;
a third lower contact disposed on a first portion of the first metal pattern and extending in the vertical direction; and
a fourth lower contact disposed on a second portion of the first metal pattern and extending in the vertical direction, and
wherein the peripheral circuit region further comprises:
a third upper contact connected to the third lower contact;
a first circuit connected to the third upper contact;
a fourth upper contact connected to the fourth lower contact; and
a second circuit connected to the fourth upper contact.

11. The memory device of claim 10, wherein the dummy region further comprises:
a second metal pattern adjacent the first metal pattern in the third layer and extending in the first horizontal direction;
a first via contact disposed on the second metal pattern and extending in the vertical direction;
a third metal pattern in contact with the first via contact at a fourth layer and extending in the second horizontal direction;
a fifth lower contact disposed on the second metal pattern and extending in the vertical direction; and
a sixth lower contact disposed on the third metal pattern and extending in the vertical direction, and
wherein the peripheral circuit region further comprises:
a fifth upper contact connected to the fifth lower contact;
a third circuit connected to the fifth upper contact;
a sixth upper contact connected to the sixth lower contact; and
a fourth circuit connected to the sixth upper contact.

12. The memory device of claim 12, wherein the dummy region further comprises:
a fourth metal pattern extending in the first horizontal direction at the third layer;
a second via contact disposed on the first metal pattern and extending in the vertical direction;
a fifth metal pattern in contact with the first via contact at a fourth layer and extending in the second horizontal direction;
a seventh lower contact disposed on the fourth metal pattern and extending in the vertical direction; and
an eighth lower contact disposed on the fifth metal pattern and extending in the vertical direction, and
wherein the peripheral circuit region further comprises:
a seventh upper contact connected to the seventh lower contact;
a first test circuit connected to the seventh upper contact;
an eighth upper contact connected to the eighth lower contact; and
a second test circuit connected to the eighth upper contact.

13. The memory device of claim 12, wherein a resistance of the fourth metal pattern is equal to a resistance of the fifth metal pattern.

14. The memory device of claim 9, wherein a resistance of the first power metal pattern is equal to a resistance of the second power metal pattern, and
wherein a voltage level of a first supply voltage applied to the first power metal pattern is different from a voltage level of a second supply voltage applied to the second power metal pattern.

15. The memory device of claim 9, wherein the first lower contact comprises:
at least one first contact metal pattern disposed on the first power metal pattern and extending toward the peripheral circuit region; and
a first contact pad disposed between the at least one first contact metal pattern and the first upper contact, and
wherein the second lower contact comprises:
at least one second contact metal pattern disposed on the second power metal pattern and extending toward the peripheral circuit region; and
a second contact pad disposed between the at least one second contact metal pattern and the second upper contact.

16. The memory device of claim 15, wherein the first upper contact comprises:
at least one third contact metal pattern in contact with the first power circuit and extending toward the dummy region; and
a third contact pad disposed between the at least one third contact metal pattern and the first contact pad, and
wherein the second upper contact comprises:
at least one fourth contact metal pattern in contact with the second power circuit and extending toward the dummy region; and
a fourth contact pad disposed between the at least one fourth contact metal pattern and the second contact pad.

17. A memory device comprising:
a plurality of sub-array regions each comprising a plurality of memory cells;
a dummy region adjacent the plurality of sub-array regions, the dummy region comprising a first metal pattern extending in a first horizontal direction at a first layer, a first via contact extending in a vertical direction on the first metal pattern, a second metal pattern in contact with the first via contact at a second layer and extending in a second horizontal direction, a first lower contact extending in the vertical direction on the first metal pattern, and a second lower contact extending in the vertical direction on the second metal pattern; and
a peripheral circuit region comprising a first upper contact connected to the first lower contact, a first test circuit connected to the first upper contact, a second upper contact connected to the second lower contact, and a second test circuit connected to the second upper contact.

18. The memory device of claim 17, wherein the dummy region further comprises:
a third metal pattern extending in the first horizontal direction at a third layer;
a third lower contact disposed on a first portion of the third metal pattern and extending in the vertical direction; and
a fourth lower contact disposed on a second portion of the third metal pattern and extending in the vertical direction, and
wherein the peripheral circuit region further comprises:
a third upper contact connected to the third lower contact;
a first circuit connected to the third upper contact;
a fourth upper contact connected to the fourth lower contact; and
a second circuit connected to the fourth upper contact.

19. The memory device of claim 18, wherein a resistance of the third metal pattern is less than a resistance of at least one of the first metal pattern and the second metal pattern.

20. The memory device of claim 17, wherein the dummy region further comprises:
a first power metal pattern extending in the first horizontal direction at a third layer;
a fifth lower contact disposed on the first power metal pattern and extending in the vertical direction;
a second power metal pattern extending in the second horizontal direction at a fourth layer; and
a sixth lower contact disposed on the second power metal pattern and extending in the vertical direction, and
wherein the peripheral circuit region further comprises:
a fifth upper contact connected to the fifth lower contact;
a first power circuit connected to the fifth upper contact;
a sixth upper contact connected to the sixth lower contact; and
a second power circuit connected to the sixth upper contact.
